(19) United States
(12) Patent Application Publication
(10) Pub. No.: US 2012/0068165 A1
(43) Pub. Date: Mar. 22, 2012

(54) ORGANIC ELECTROLUMINESCENCE ELEMENT

(76) Inventor: Masayuki HAYASHI, Ashigarakami-gun (JP)

(21) Appl. No.: 13/305,345

(22) Filed: Nov. 28, 2011

Related U.S. Application Data
(63) Continuation-in-part of application No. PCT/JP2010/056489, filed on Apr. 5, 2010.

(30) Foreign Application Priority Data
May 29, 2009 (JP) 2009-131194

(51) Int. Cl. H01L 51/54

(52) U.S. Cl. 257/40; 257/E51.024

(57) ABSTRACT

An organic electroluminescence element including: an anode, a cathode, and at least one organic layer which includes a light emitting layer, and which is provided between the anode and the cathode, wherein at least one layer in the organic layer contains at least one selected from nitrogen-containing heterocyclic derivatives each represented by the following General Formula (1) and used as at least one of an electron injecting material and an electron transporting material, and at least one layer in the organic layer contains at least one selected from phosphorescence emitting materials having structures expressed by the following Structural Formulae (I-1) to (I-4), (I-7) to (I-12), (I-14) and (I-16) to (I-26):

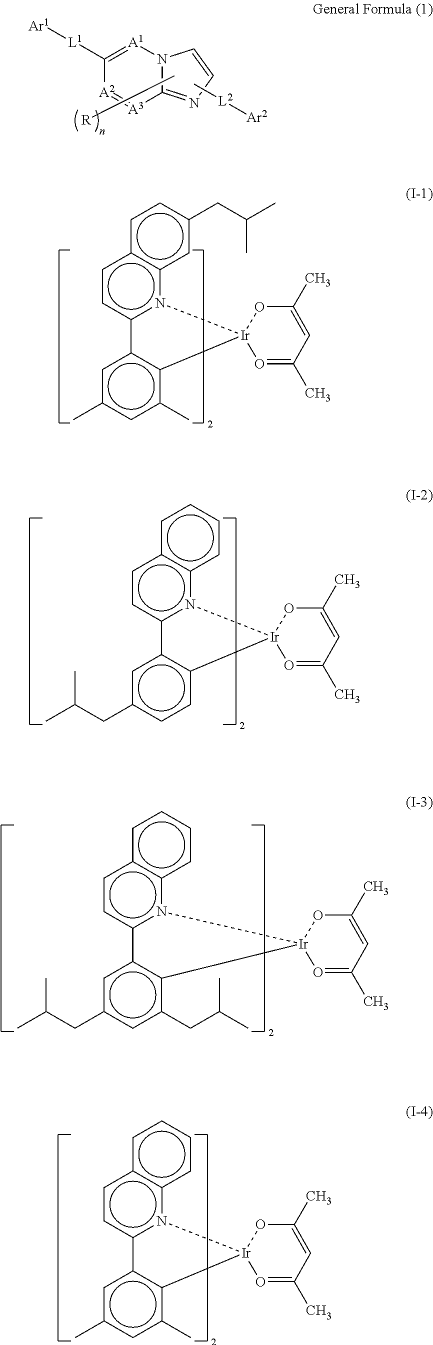

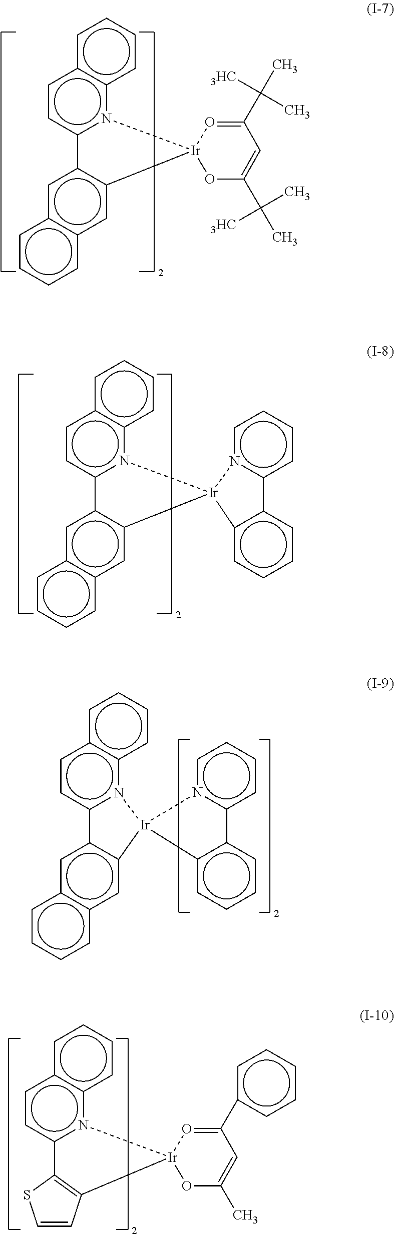

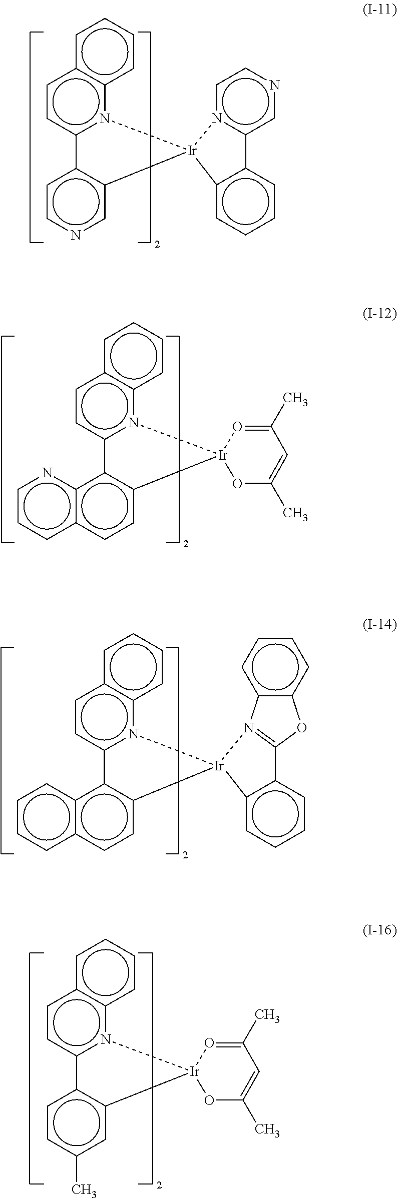

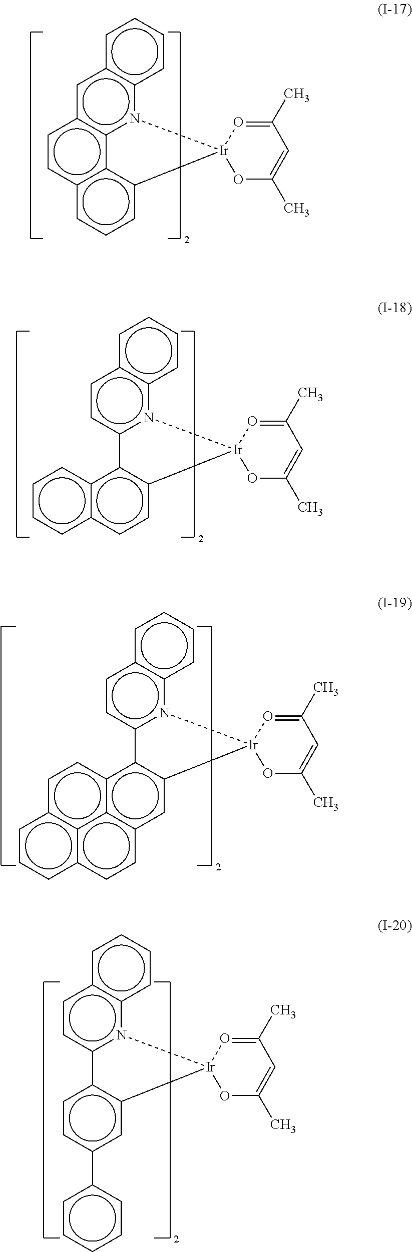

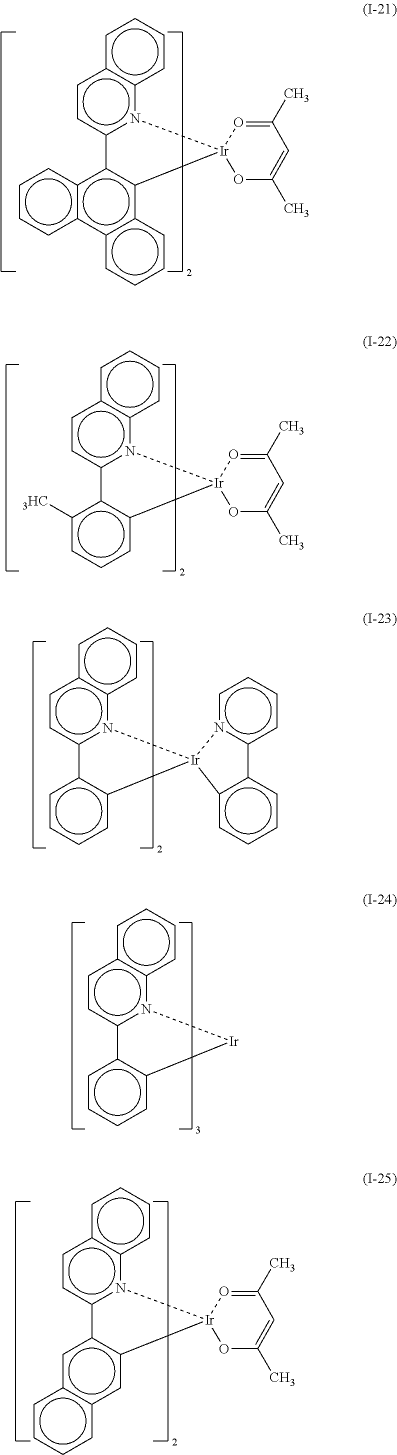

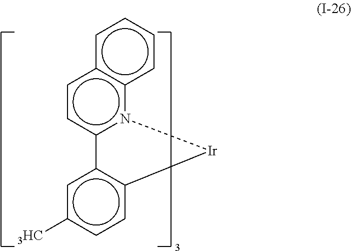

This is a continuation-in-part of International Application PCT/JP2010/056489, with an international filing date of 5 Apr. 2010, which is pending.

### BACKGROUND OF THE INVENTION

1. Field of the Invention

The present invention relates to an organic electroluminescence element (hereinbelow, otherwise referred to as “organic electroluminescent element” or “organic EL element”).

2. Description of the Related Art

Organic EL elements have features of self light emitting capability and high-speed responsibility and are expected to be used in flat panel displays. In particular, since a two-layered (laminated) organic EL element in which a hole-transporting organic thin film (hole transporting layer) and an electron-transporting organic thin film (electron transporting layer) was reported, substantial attention has been paid to the two-layered organic EL element as a large-area light emitting element which emits light at a low voltage of 10V or less. A laminated organic EL element has, as a basic structure, a positive electrode/a hole transporting layer/a light emitting layer/an electron transporting layer/a negative electron. Of these components, the hole transporting layer or the electron transporting layer may function as the light emitting layer, as in the case with the two-layered organic EL element.

In this type organic EL element, as a hole transporting material for use in a hole transporting layer, generally, many materials having a high mobility of holes have been known. With use such a material, it is relatively easy to transport a sufficient amount of holes into a light emitting layer.

In contrast, most of electron transporting materials for use in electron transporting layers have a low mobility of electrons as compared with the mobility of holes of hole transporting materials. Therefore, a sufficient amount of electrons cannot be transported into a light emitting layer, and the carrier balance in the light emitting layer is disturbed, causing problems with degradation in the light emitting efficiency and a decrease in the light emission life. Especially, in red phosphorescence emitting elements, Ir-based materials serving as red phosphorescence emitting materials are generally hole transportable and have drawbacks in that the carrier balance in the light emitting layer is poor and the properties significantly degrades

There has been proposed an organic EL element which is capable of both low-voltage use and high light emitting efficiency by using, as a high electron transporting material, a specific nitrogen-containing heterocyclic derivative in its electron injection layer and an electron transporting layer (for example, see Japanese Patent Application Laid-Open (JP-A) No. 2004-217547). This proposal, however, includes no description of examples using a phosphorescence emitting material, does not bring up a problem that when a phosphorescence emitting material is used, it is impossible to obtain sufficient light efficiency, and does not disclose or suggest a technique for obtaining high light emitting efficiency and long light emission life, concerning which combination of materials is used with which type phosphorescence material, although examples of using fluorescence emitting elements are disclosed.

Meanwhile, there has been proposed an organic EL element capable of high light emitting efficiency by using, as a red phosphorescence emitting material, a phenyl quinoline Ir complex (for example, see Japanese Patent Application Laid-Open (JP-A) No. 2001-345183). However, the organic EL element in this proposal is further required to improve the light emitting efficiency, and has no disclosure or suggestion of a technique for prolonging light emission life

Accordingly, it is strongly required to promptly develop an organic EL element capable of satisfying both excellent light emitting efficiency and long light emission life.

### BRIEF SUMMARY OF THE INVENTION

The present invention aims to solve the above-mentioned various problems and to achieve the following object. That is, the object of the present invention is to provide an organic electroluminescence element capable of satisfying both excellent light emitting efficiency and long light emission life.

As a result of carrying out extensive studies and examinations in an attempt to solve the above-mentioned problems, the present inventors have found that with use of a nitrogen-containing heterocyclic derivative which has a high mobility of electrons, and an Ir complex, it is possible to improve the light emitting efficiency of an organic electroluminescence element and to prolong the light-emitting life, and in particular, among Ir complexes, with use of an phenylquinoline Ir complex, it is possible to remarkably improve the light emitting efficiency and to significantly prolong the light emitting life.

The present invention is made based on the knowledge and findings of the present inventors. Means for solving the above-mentioned problems are as follows:

<1> An organic electroluminescence element including:

an anode,

a cathode, and

at least one organic layer which includes a light emitting layer, and which is provided between the anode and the cathode,

wherein at least one layer in the organic layer contains at least one selected from nitrogen-containing heterocyclic derivatives each represented by the following General Formula (1), and at least one layer in the organic layer contains at least one selected from a phosphorescence emitting material represented by the following General Formula (2A), a phosphorescence emitting material represented by the following General Formula (2B) and a phosphorescence emitting material represented by the following General Formula (2C):

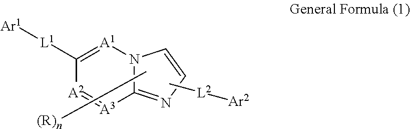

where A¹ to A³ independently represent a nitrogen atom or a carbon atom; Ar¹ represents a substituted or unsubstituted aryl group having 6 to 60 nuclear carbon atoms or a substituted or unsubstituted heteroaryl group having 3 to 60 nuclear carbon atoms; Ar² represents any one of a hydrogen atom, a substituted or unsubstituted aryl group having 6 to 60 nuclear carbon atoms, a substituted or unsubstituted heteroaryl group having 3 to 60 nuclear carbon atoms, a substituted or unsubstituted alkyl group having 1 to 20 carbon atoms and a substituted or unsubstituted alkoxy group having 1 to 20 carbon atoms, provided that one of Ar¹ and Ar² is a substituted or unsubstituted condensed ring group having 10 to 60 nuclear carbon atoms or a substituted or unsubstituted monohetero-condensed ring group having 3 to 60 nuclear carbon atoms; L¹ and L² independently represent any one of a single bond, a substituted or unsubstituted arylene group having 6 to 60 nuclear carbon atoms, a substituted or unsubstituted heteroarylene group having 3 to 60 nuclear carbon atoms and a substituted or unsubstituted fluorenylene group; R represents any one of a hydrogen atom, a substituted or unsubstituted aryl group having 6 to 60 nuclear carbon atoms, a substituted or unsubstituted heteroaryl group having 3 to 60 nuclear carbon atoms, a substituted or unsubstituted alkyl group having 1 to 20 carbon atoms and a substituted or unsubstituted alkoxy group having 1 to 20 carbon atoms; n is an integer of 0 to 5, and when n is 2 or more, Rs may be identical to or different from each other, and adjacent R groups may be bonded to each other to form a carbon cyclic aliphatic ring or a carbon cyclic aromatic ring,

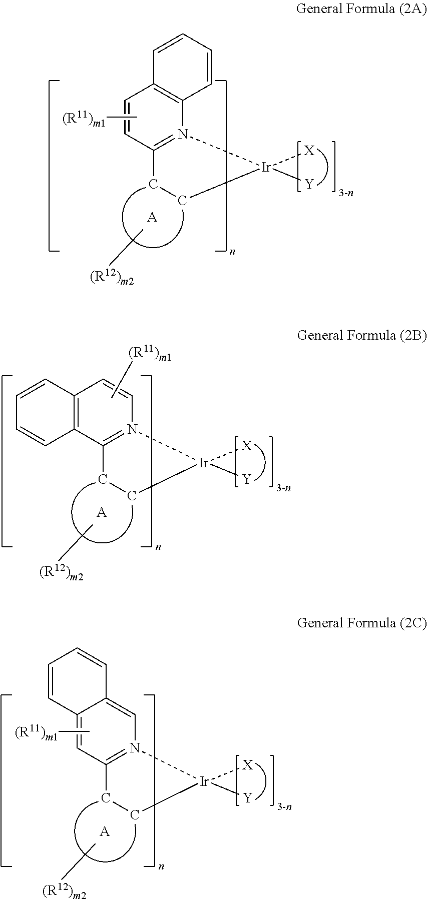

in General Formulae (2A), (2B) and (2C), n is an integer of 1 to 3; X-Y represents a bidentate ligand; ring A represents a cyclic structure that may contain any one of a nitrogen atom, a sulfur atom and an oxygen atom; R¹¹ represents a substituent, m1 is an integer of 0 to 6, and when m1 is 2 or more, adjacent R¹¹ substituents may be bonded to each other to form a ring that may contain any one of a nitrogen atom, a sulfur atom and an oxygen atom, and the ring may further have a substituent; R¹² represents a substituent, m2 is an integer of 0 to 4, when m2 is 2 or more, adjacent R¹² substituents may be bonded to each other to form a ring that may contain any one of a nitrogen atom, a sulfur atom and an oxygen atom, and the ring may further have a substituent; and R¹¹ and R¹² may be bonded to each other to form a ring that may contain any one of a nitrogen atom, a sulfur atom and an oxygen atom, and the ring may further have a substituent.

<2> The organic electroluminescence element according to <1>, wherein the nitrogen-containing heterocyclic derivative represented by General Formula (1) is a nitrogen-containing heterocyclic derivative represented by the following General Formula (4):

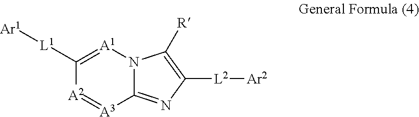

where A¹ to A³ independently represent a nitrogen atom or a carbon atom; Ar¹ represents a substituted or unsubstituted aryl group having 6 to 60 nuclear carbon atoms or a substituted or unsubstituted heteroaryl group having 3 to 60 nuclear carbon atoms; Ar² represents any one of a hydrogen atom, a substituted or unsubstituted aryl group having 6 to 60 nuclear carbon atoms, a substituted or unsubstituted heteroaryl group having 3 to 60 nuclear carbon atoms, a substituted or unsubstituted alkyl group having 1 to 20 carbon atoms and a substituted or unsubstituted alkoxy group having 1 to 20 carbon atoms, provided that one of Ar¹ and Ar² is a substituted or unsubstituted condensed ring group having 10 to 60 nuclear carbon atoms or a substituted or unsubstituted monohetero-condensed ring group having 3 to 60 nuclear carbon atoms; L¹ and L² independently represent any one of a single bond, a substituted or unsubstituted arylene group having 6 to 60 nuclear carbon atoms, a substituted or unsubstituted heteroarylene group having 3 to 60 nuclear carbon atoms and a substituted or unsubstituted fluorenylene group; and R′ represents any one of a hydrogen atom, a substituted or unsubstituted aryl group having 6 to 60 nuclear carbon atoms, a substituted or unsubstituted heteroaryl group having 3 to 60 nuclear carbon atoms, a substituted or unsubstituted alkyl group having 1 to 20 carbon atoms and a substituted or unsubstituted alkoxy group having 1 to 20 carbon atoms.

<3> The organic electroluminescence element according to <2>, wherein the nitrogen-containing heterocyclic derivative represented by General Formula (4) is a nitrogen-containing heterocyclic derivative represented by the following General Formula (5):

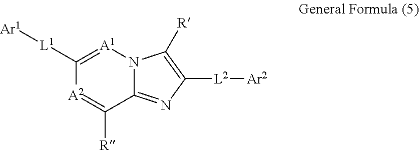

where A¹ and A² independently represent a nitrogen atom or a carbon atom; Ar¹ represents a substituted or unsubstituted aryl group having 6 to 60 nuclear carbon atoms or a substituted or unsubstituted heteroaryl group having 3 to 60 nuclear carbon atoms; Ar² represents any one of a hydrogen atom, a substituted or unsubstituted aryl group having 6 to 60 nuclear carbon atoms, a substituted or unsubstituted heteroaryl group having 3 to 60 nuclear carbon atoms, a substituted or unsubstituted alkyl group having 1 to 20 carbon atoms and a substituted or unsubstituted alkoxy group having 1 to 20 carbon atoms, provided that one of Ar¹ and Ar² is a substituted or unsubstituted condensed ring group having 10 to 60 nuclear carbon atoms or a substituted or unsubstituted monohetero-condensed ring group having 3 to 60 nuclear carbon atoms; L¹ and L² independently represent any one of a single bond, a substituted or unsubstituted arylene group having 6 to 60 nuclear carbon atoms, a substituted or unsubstituted heteroarylene group having 3 to 60 nuclear carbon atoms and a substituted or unsubstituted fluorenylene group; R′ and R″ independently represent any one of a hydrogen atom, a substituted or unsubstituted aryl group having 6 to 60 nuclear carbon atoms, a substituted or unsubstituted heteroaryl group having 3 to 60 nuclear carbon atoms, a substituted or unsubstituted alkyl group having 1 to 20 carbon atoms and a substituted or unsubstituted alkoxy group having 1 to 20 carbon atoms, and R′ and R″ may be identical to or different from each other.

<4> The organic electroluminescence element according to any one of <1> to <3>, wherein in the nitrogen-containing heterocyclic derivative represented by at least one of General Formulae (1), (4), and (5), at least one of L¹ and L² is selected from groups represented by the following structural formulae:

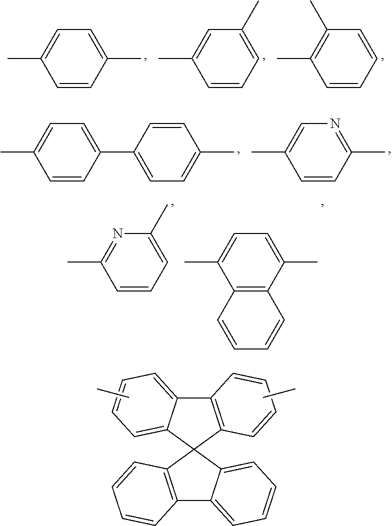

<5> The organic electroluminescence element according to any one of <1> to <4>, wherein in the nitrogen-containing heterocyclic derivative represented by at least one of General Formulae (1), (4), and (5), Ar¹ is selected from groups represented by the following General Formulae (6) to (15):

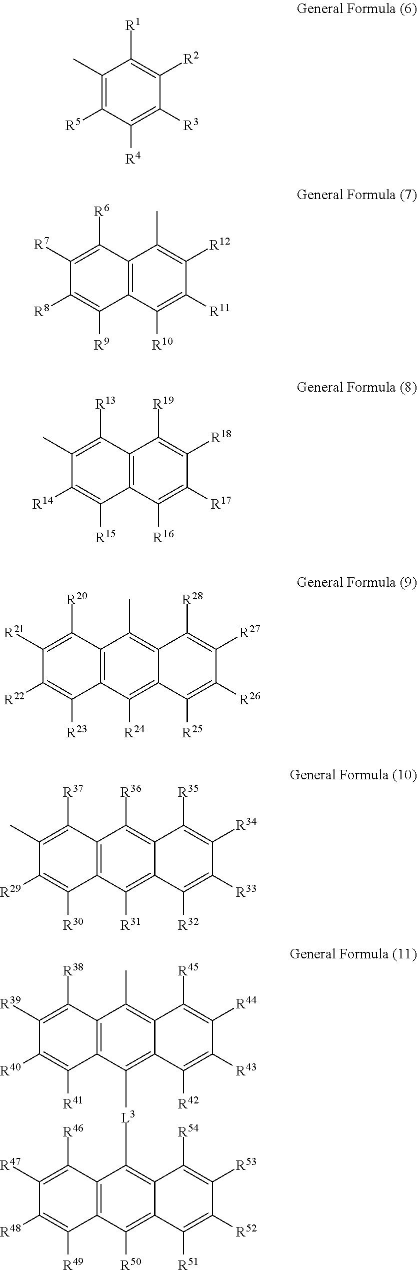

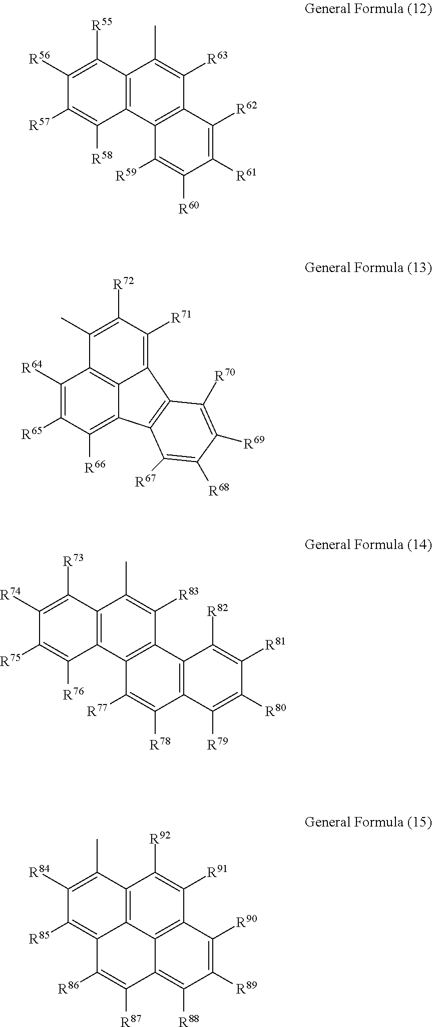

In General Formulae (6) to (15), R¹ to R⁹² independently represent any one of a hydrogen atom, a halogen atom, a substituted or unsubstituted alkyl group having 1 to 20 carbon atoms, a substituted or unsubstituted alkoxy group having 1 to 20 carbon atoms, a substituted or unsubstituted aryloxy group having 6 to 40 nuclear carbon atoms, a substituted or unsubstituted diarylamino group having 12 to 80 nuclear carbon atoms, a substituted or unsubstituted aryl group having 6 to 40 nuclear carbon atoms, a substituted or unsubstituted heteroaryl group having 3 to 40 nuclear carbon atoms and a substituted or unsubstituted diarylaminoaryl group having 18 to 120 nuclear carbon atoms; and L³ represents one of a single bond and a substituent represented by any one of the following structural formulae:

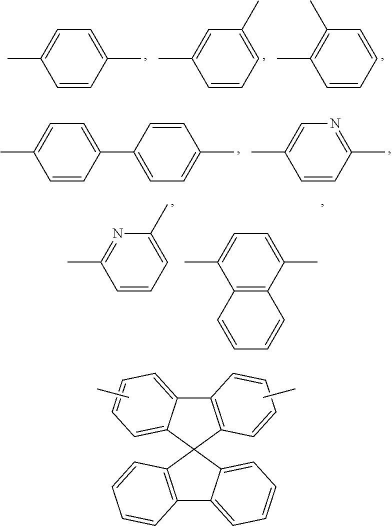

<6> The organic electroluminescence element according to any one of <1> to <5>, wherein the light emitting layer contains at least one selected from the phosphorescence emitting material represented by General Formula (2A), the phosphorescence emitting material represented by General Formula (2B) and the phosphorescence emitting material represented by General Formula (2C).
<7> The organic electroluminescence element according to any one of <1> to <6>, wherein the nitrogen-containing heterocyclic derivative is used as at least one of an electron injecting material and an electron transporting material.
<8> The organic electroluminescence element according to any one of <1> to <7>, wherein the layer containing the nitrogen-containing heterocyclic derivative contains a reducing dopant.
<9> The organic electroluminescence element according to <8>, wherein the reducing dopant is at least one selected from alkali metals, alkaline earth metals, rare earth metals, oxides of alkali metals, halides of alkali metals, oxides of alkaline earth metals, halides of alkaline earth metals, oxide of rare earth metals, halides of rare earth metals, organic complexes of alkali metals, organic complexes of alkaline earth metals, and organic complexes of rare earth metals.

According to the present invention, it is possible to solve the above-mentioned conventional problems, to achieve the object and to provide an organic electroluminescence element capable of satisfying both excellent light emission efficiency and long light-emitting life.

### BRIEF DESCRIPTION OF THE DRAWINGS

FIG. 1 is a schematic diagram illustrating one example of a layer configuration of an organic electroluminescence element according to the present invention.

### DETAILED DESCRIPTION OF THE INVENTION

### (Organic Electroluminescence Element)

The organic electroluminescence element of the present invention includes an anode, a cathode, and at least one organic layer, at least one layer in the organic layer contains at least one selected from specific nitrogen-containing heterocyclic derivatives, and at least one layer in the organic layer contains at least one specific phosphorescence emitting material.

### <Nitrogen-Containing Heterocyclic Derivative>

The nitrogen-containing heterocyclic derivative contains at least one selected from nitrogen-containing heterocyclic derivatives each represented by the following General Formula (1).

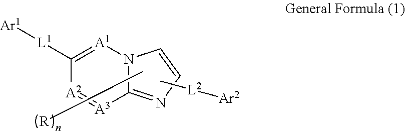

where A¹ to A³ independently represent a nitrogen atom or a carbon atom; Ar¹ represents a substituted or unsubstituted aryl group having 6 to 60 nuclear carbon atoms or a substituted or unsubstituted heteroaryl group having 3 to 60 nuclear carbon atoms; Ar² represents any one of a hydrogen atom, a substituted or unsubstituted aryl group having 6 to 60 nuclear carbon atoms, a substituted or unsubstituted heteroaryl group having 3 to 60 nuclear carbon atoms, a substituted or unsubstituted alkyl group having 1 to 20 carbon atoms and a substituted or unsubstituted alkoxy group having 1 to 20 carbon atoms, provided that one of Ar¹ and Ar² is a substituted or unsubstituted condensed ring group having 10 to 60 nuclear carbon atoms or a substituted or unsubstituted monohetero-condensed ring group having 3 to 60 nuclear carbon atoms; L¹ and L² independently represent any one of a single bond, a substituted or unsubstituted arylene group having 6 to 60 nuclear carbon atoms, a substituted or unsubstituted heteroarylene group having 3 to 60 nuclear carbon atoms and a substituted or unsubstituted fluorenylene group; R represents any one of a hydrogen atom, a substituted or unsubstituted aryl group having 6 to 60 nuclear carbon atoms, a substituted or unsubstituted heteroaryl group having 3 to 60 nuclear carbon atoms, a substituted or unsubstituted alkyl group having 1 to 20 carbon atoms and a substituted or unsubstituted alkoxy group having 1 to 20 carbon atoms; n is an integer of 0 to 5, and when n is 2 or more, Rs may be identical to or different from each other, and adjacent R groups may be bonded to each other to form a carbon cyclic aliphatic ring or a carbon cyclic aromatic ring.

The nitrogen-containing heterocyclic derivative represented by General Formula (1) is preferably a nitrogen-containing heterocyclic derivative represented by the following General Formula (4).

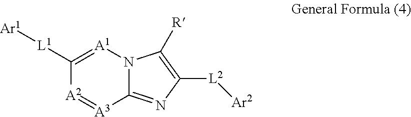

In General Formula (4), A¹ to A³ independently represent a nitrogen atom or a carbon atom; Ar¹ represents a substituted or unsubstituted aryl group having 6 to 60 nuclear carbon atoms or a substituted or unsubstituted heteroaryl group having 3 to 60 nuclear carbon atoms; Ar² represents any one of a hydrogen atom, a substituted or unsubstituted aryl group having 6 to 60 nuclear carbon atoms, a substituted or unsubstituted heteroaryl group having 3 to 60 nuclear carbon atoms, a substituted or unsubstituted alkyl group having 1 to 20 carbon atoms and a substituted or unsubstituted alkoxy group having 1 to 20 carbon atoms, provided that one of Ar¹ and Ar² is a substituted or unsubstituted condensed ring group having 10 to 60 nuclear carbon atoms or a substituted or unsubstituted monohetero-condensed ring group having 3 to 60 nuclear carbon atoms.

L¹ and L² independently represent any one of a single bond, a substituted or unsubstituted arylene group having 6 to 60 nuclear carbon atoms, a substituted or unsubstituted heteroarylene group having 3 to 60 nuclear carbon atoms and a substituted or unsubstituted fluorenylene group.

R′ represents any one of a hydrogen atom, a substituted or unsubstituted aryl group having 6 to 60 nuclear carbon atoms, a substituted or unsubstituted heteroaryl group having 3 to 60 nuclear carbon atoms, a substituted or unsubstituted alkyl group having 1 to 20 carbon atoms and a substituted or unsubstituted alkoxy group having 1 to 20 carbon atoms.

The nitrogen-containing heterocyclic derivative represented by General Formula (4) is preferably a nitrogen-containing heterocyclic derivative represented by the following General Formula (5).

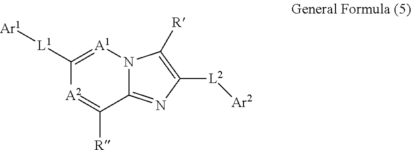

In General Formula (5), A¹ and A² independently represent a nitrogen atom or a carbon atom.

Ar¹ represents a substituted or unsubstituted aryl group having 6 to 60 nuclear carbon atoms or a substituted or unsubstituted heteroaryl group having 3 to 60 nuclear carbon atoms; Ar² represents any one of a hydrogen atom, a substituted or unsubstituted aryl group having 6 to 60 nuclear carbon atoms, a substituted or unsubstituted heteroaryl group having 3 to 60 nuclear carbon atoms, a substituted or unsubstituted alkyl group having 1 to 20 carbon atoms and a substituted or unsubstituted alkoxy group having 1 to 20 carbon atoms, provided that one of Ar¹ and Ar² is substituted or unsubstituted condensed ring group having 10 to 60 nuclear carbon atoms or a substituted or unsubstituted monohetero-condensed ring group having 3 to 60 nuclear carbon atoms.

L¹ and L² independently represent any one of a single bond, a substituted or unsubstituted arylene group having 6 to 60 nuclear carbon atoms, a substituted or unsubstituted heteroarylene group having 3 to 60 nuclear carbon atoms and a substituted or unsubstituted fluorenylene group.

R′ and R″ independently represent any one of a hydrogen atom, a substituted or unsubstituted aryl group having 6 to 60 nuclear carbon atoms, a substituted or unsubstituted heteroaryl group having 3 to 60 nuclear carbon atoms, a substituted or unsubstituted alkyl group having 1 to 20 carbon atoms and a substituted or unsubstituted alkoxy group having 1 to 20 carbon atoms, and R′ and R″ may be identical to or different from each other.

In the nitrogen-containing heterocyclic derivative represented by at least one of General Formulae (1), (4), and (5), at least one of L¹ and L² is selected from groups represented by the following structural formulae:

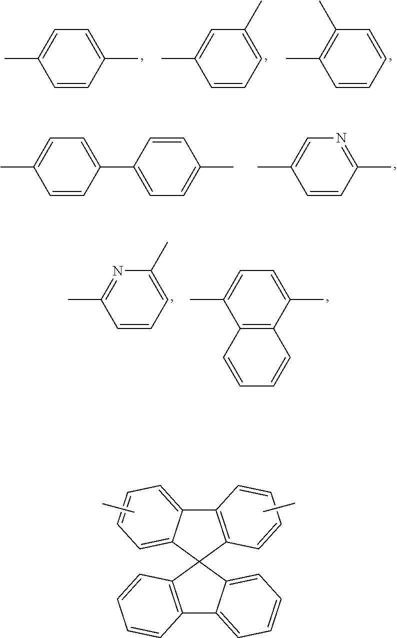

in the nitrogen-containing heterocyclic derivative represented by at least one of General Formulae (1), (4), and (5), Ar¹ is selected from groups represented by the following General Formulae (6) to (15):

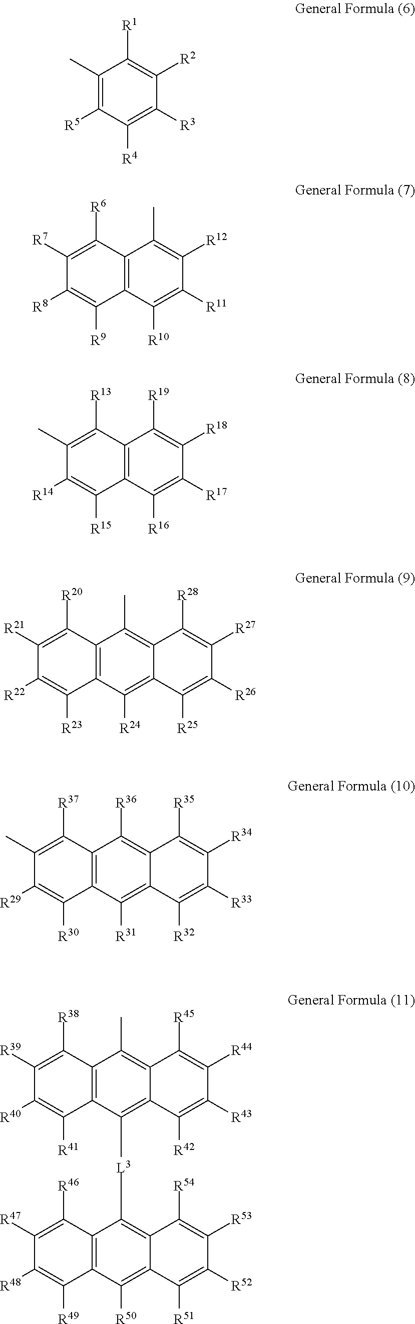

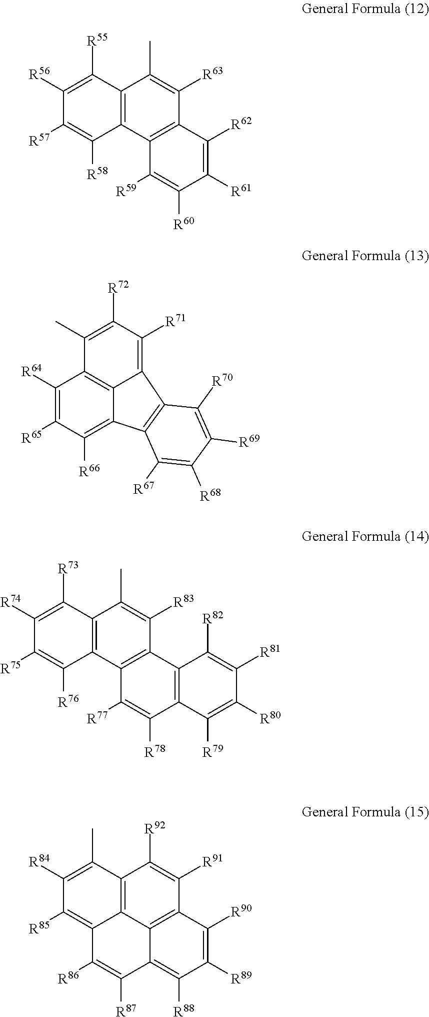

in General Formulae (6) to (15), R¹ to R⁹² independently represent any one of a hydrogen atom, a halogen atom, a substituted or unsubstituted alkyl group having 1 to 20 carbon atoms, a substituted or unsubstituted alkoxy group having 1 to 20 carbon atoms, a substituted or unsubstituted aryloxy group having 6 to 40 nuclear carbon atoms, a substituted or unsubstituted diarylamino group having 12 to 80 nuclear carbon atoms, a substituted or unsubstituted aryl group having 6 to 40 nuclear carbon atoms, a substituted or unsubstituted heteroaryl group having 3 to 40 nuclear carbon atoms and a substituted or unsubstituted diarylaminoaryl group having 18 to 120 nuclear carbon atoms; and L³ represents one of a single bond and a substituent represented by any one of the following structural formulae:

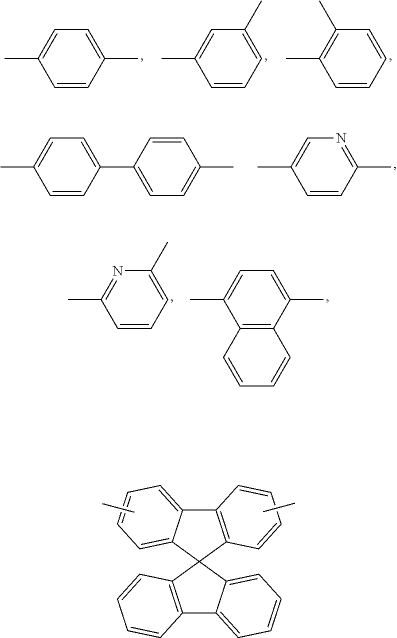

Specific examples of a nitrogen-containing heterocyclic derivative that may be used in the present invention include the following compounds, but not limited thereto.

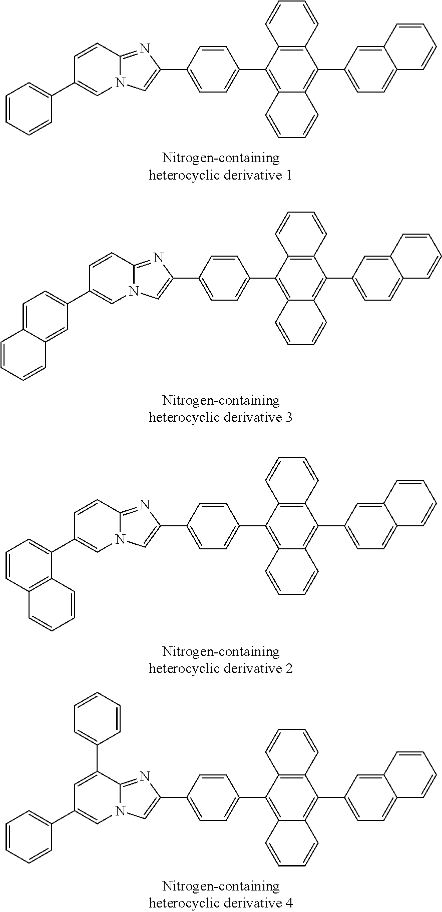

The nitrogen-containing heterocyclic derivative is preferably used as at least one of an electron injecting material and an electron transporting material.

The nitrogen-containing heterocyclic derivative is contained in at least one layer in the organic layer, and it is preferably contained in at least one of an electron injection layer and an electron transporting layer.

The electron injection layer and the electron transporting layer are layers having functions for receiving electrons from a cathode or from a cathode side, and transporting electrons to an anode side.

The thickness of the organic layer containing a nitrogen-containing heterocyclic derivative is not particularly limited and may be suitably adjusted in accordance with the intended use. For instance, when the nitrogen-containing heterocyclic derivative is contained in the electron injection layer or the electron transporting layer, the thickness thereof is preferably 0.5 nm to 500 nm, more preferably 1 nm to 200 nm.

The layer containing a nitrogen-containing heterocyclic derivative (organic layer, electron injection layer, electron transporting layer) preferably contains a reducing dopant.

The reducing dopant is not particularly limited and may be suitably selected in accordance with the intended use. The reducing dopant is, however, preferably at least one selected from alkali metals, alkaline earth metals, rare earth metals, oxides of alkali metals, halides of alkali metals, oxides of alkaline earth metals, halides of alkaline earth metals, oxide of rare earth metals, halides of rare earth metals, organic complexes of alkali metals, organic complexes of alkaline earth metals, and organic complexes of rare earth metals.

The amount of use of the reducing dopant varies depending on the type of material of the layer into which the dopant is incorporated, however, it is preferably 0.1% by mass to 99% by mass, more preferably 0.3% by mass to 80% by mass, still more preferably 0.5% by mass to 50% by mass, with respect to the electron transporting layer material or electron injecting material.

The electron transporting layer and the electron injection layer can be formed by a known method. These layers can be suitably formed, for example, by a vapor deposition method, wet-process film forming method, MBE (Molecular Beam epitaxy) method, cluster ion beam method, molecular lamination method, LB method, printing method, and transfer method, etc.

The thickness of the electron transporting layer is not particularly limited and may be suitably selected in accordance with the intended use. It is, however, preferably 1 nm to 200 nm, more preferably 1 nm to 100 nm, still more preferably 1 nm to 50 nm.

The thickness of the electron injection layer is not particularly limited and may be suitably selected in accordance with the intended use. It is, however, preferably 1 nm to 200 nm, more preferably 1 nm to 100 nm, still more preferably 1 nm to 50 nm.

### <Phosphorescence Emitting Material>

The phosphorescence emitting material contains at least one of compounds represented by any one of a phosphorescence emitting material represented by the following General Formula (2A), a phosphorescence emitting material represented by the following General Formula (2B) and a phosphorescence emitting material represented by the following General Formula (2C).

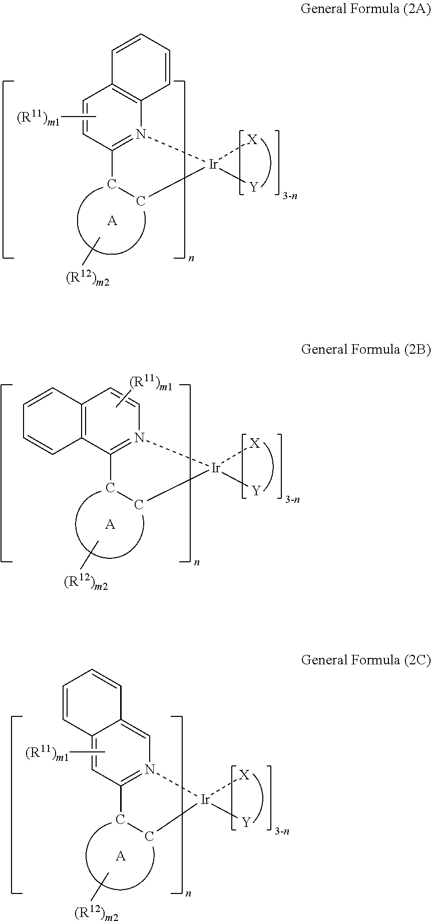

In General Formulae (2A), (2B) and (2C), n is an integer of 1 to 3; X-Y represents a bidentate ligand; ring A represents a cyclic structure that may contain any one of a nitrogen atom, a sulfur atom and an oxygen atom; R¹¹ represents a substituent, m1 is an integer of 0 to 6, and when m1 is 2 or more, adjacent R¹¹ substituents may be bonded to each other to form a ring that may contain any one of a nitrogen atom, a sulfur atom and an oxygen atom, and the ring may further have a substituent; R¹² represents a substituent, m2 is an integer of 0 to 4, when m2 is 2 or more, adjacent R¹² substituents may be bonded to each other to form a ring that may contain any one of a nitrogen atom, a sulfur atom and an oxygen atom, and the ring may further have a substituent; and R¹¹ and R¹² may be bonded to each other to form a ring that may contain any one of a nitrogen atom, a sulfur atom and an oxygen atom, and the ring may further have a substituent.

The ring A represents a cyclic structure that may contain any one of a nitrogen atom, a sulfur atom and an oxygen atom. Preferred examples thereof are a five-membered ring and a six-membered ring. The ring A may have a substituent.

X-Y represents a bidentate ligand, and preferred is a bidentate monoanionic ligand.

Specific examples of the bindentate monoanionic ligand include picolinato (pic), acetylacetonate (acac), and dipivaloylmethanato (t-butyl-acac).

As bidentate monoanionic ligands other than the above-mentioned ones, there may be exemplified the ligands described, by Lamansky et. al., in pp. 89 to 91 in International Publication No. WO02/15645.

The substituents of R¹¹ and R¹² are not particularly limited and may be suitably selected in accordance with the intended use. For example, R¹¹ and R¹² each represent a halogen atom, an alkoxy group, an amino group, a cycloalkyl group, an aryl group that may contain a nitrogen atom or a sulfur atom; an aryloxy group that may contain a nitrogen atom or a sulfur atom, and they may further have a substituent.

R¹¹ and R¹² may be bonded to each other to form a ring, that may contain any one of a nitrogen atom, a sulfur atom. Preferred examples thereof are a five-membered ring and a six-membered ring. The ring may have a substituent.

As the compound represented by any one of General Formulae (2A), (2B), and (2C), for example, compounds represented by any one of the following structural formulae (I-1) to (I-27) are exemplified, but are not limited thereto.

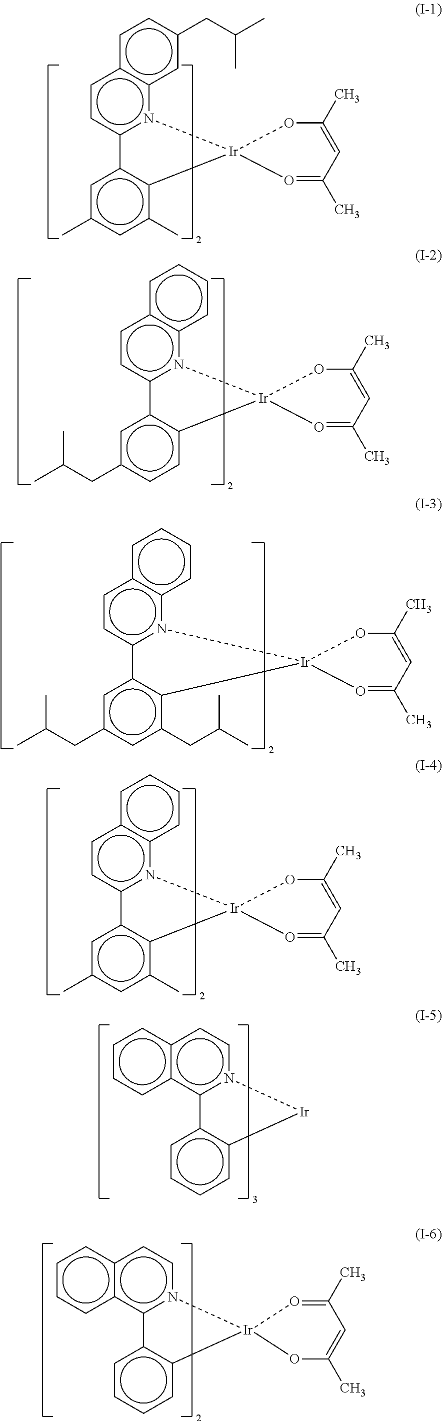

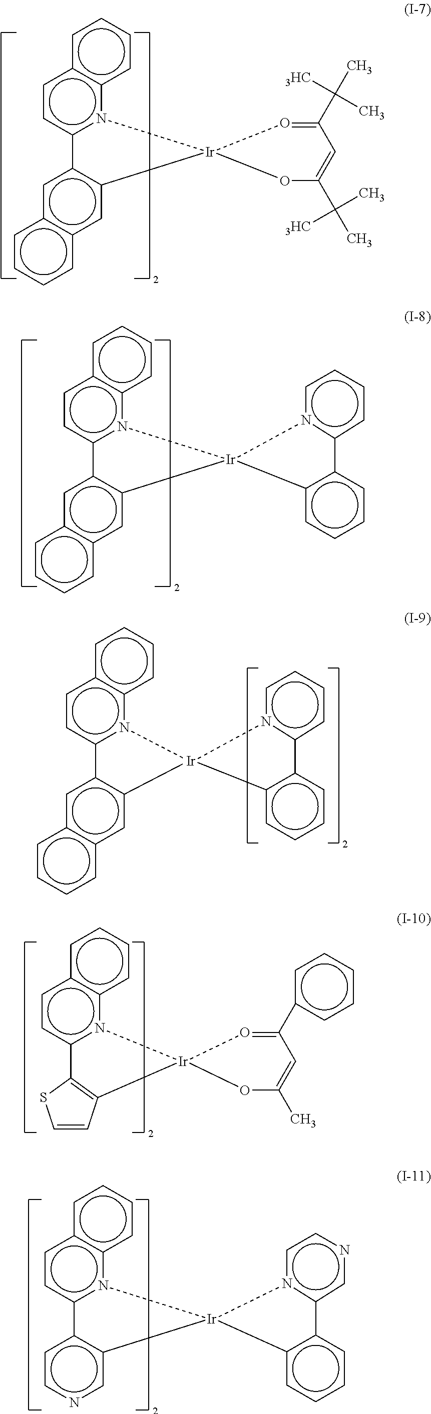

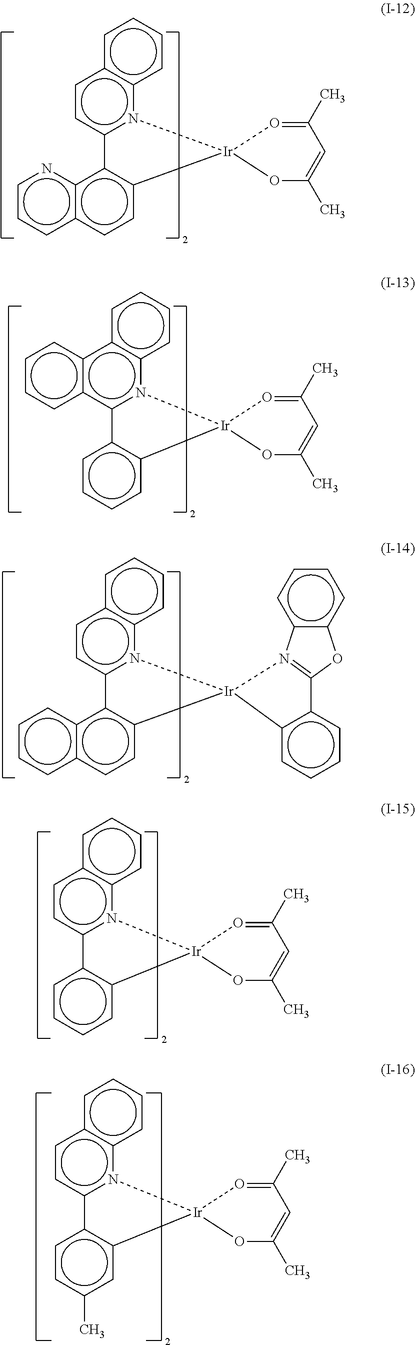

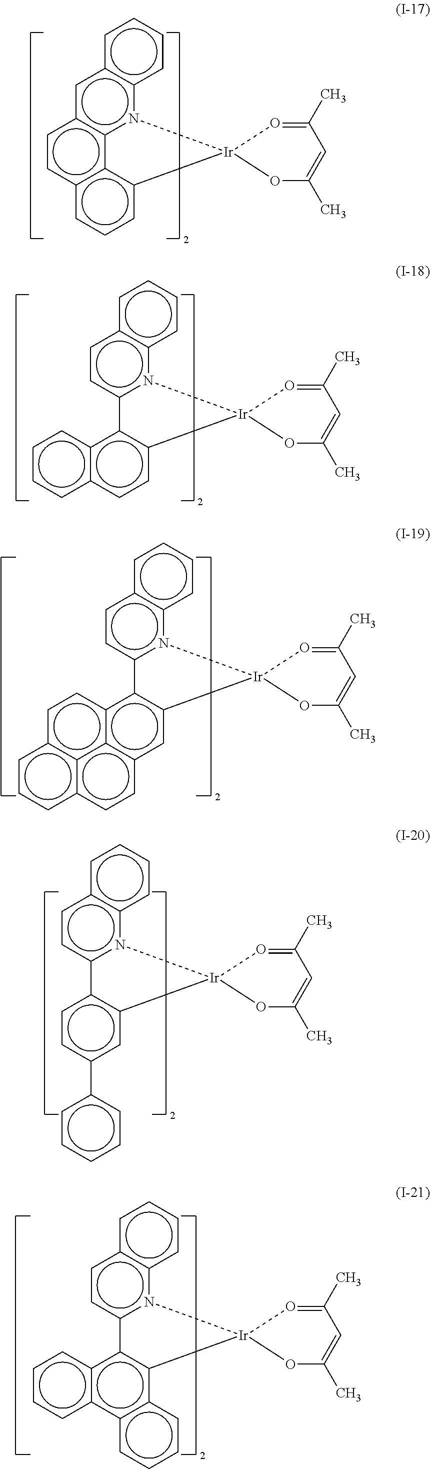

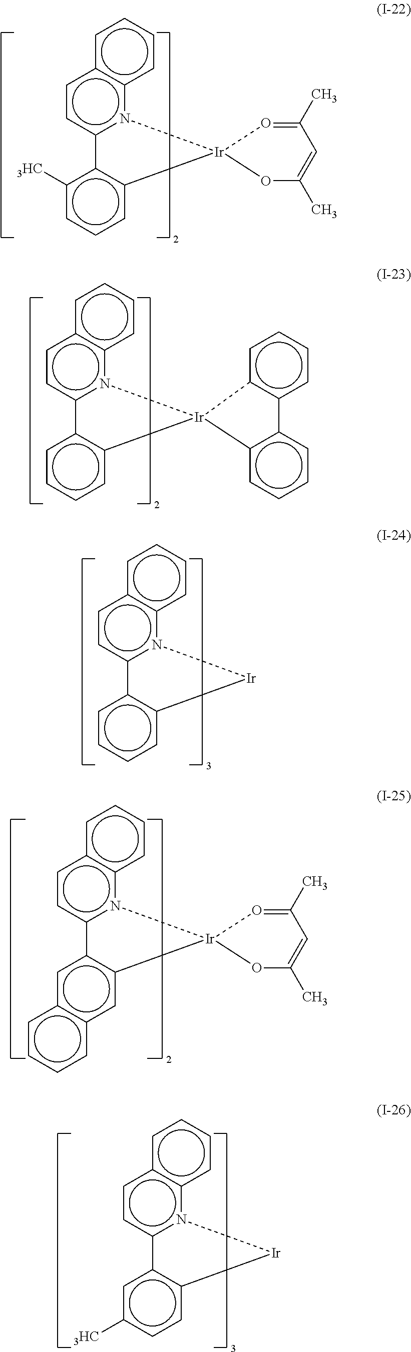

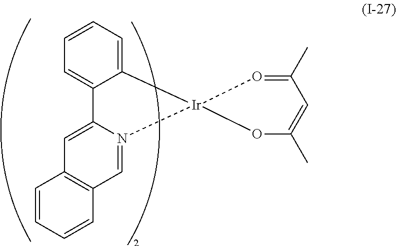

The amount of the phosphorescence emitting material is not particularly limited and may be suitably adjusted in accordance with the intended use. It is, however, preferably 0.5% by mass to 30% by mass, more preferably 1% by mass to 20% by mass, and still more preferably 2% by mass to 15% by mass, in the light emitting layer, generally, with respect to the total mass of the compound forming the light emitting layer.

When the amount of the phosphorescence emitting material is less than 0.5% by mass, a degradation in the light emitting efficiency and an increase in the voltage occur. When it is more than 30% by mass, the light emitting efficiency degrades due to the formation of associated substance of light emitting material.

The light emitting layer is a layer having functions to receive, at the time of electric field application, holes from the anode, hole injection layer or hole transporting layer, and to receive electrons from the cathode, electron injection layer or electron transporting layer, and offer the field of recombination of holes and electrons to emit light.

The light emitting layer is not particularly limited and can be formed by a known method, and can be suitably formed, for example, by a dry film-forming method such as a vapor deposition method and a sputtering method; a wet-process coating method, a transfer method, a printing method, and an inkjet method.

The thickness of the light emitting layer is not particularly limited and may be suitably selected in accordance with the intended use. The thickness is preferably 2 nm to 500 nm, and from the viewpoint of the external quantum efficiency, it is more preferably 3 nm to 200 nm, still more preferably 10 nm to 200 nm. The light emitting layer may be a single layer or may be composed of two or more layers, and each layer may emit light in different luminescent color.

### <Host Material>

The light emitting layer may contain a host material.

As the host material, both an electron transporting host and a hole transporting host can be favorably used. An electron transporting host can be used in combination with a hole transporting host.

### —Electron Transporting Host Material—

The electron transporting host material preferably has an electron affinity Ea, from the viewpoint of improvement of durability and reduction in driving electric voltage, of 2.5 eV to 3.5 eV, more preferably 2.6 eV to 3.4 eV, particularly preferably 2.8 eV to 3.3 eV, and preferably have an ionization potential Ip, from the viewpoint of improvement of durability and reduction in driving electric voltage, of 5.7 eV to 7.5 eV, more preferably 5.8 eV to 7.0 eV, particularly preferably 5.9 eV to 6.5 eV.

The lowest triplet excitation energy (hereinbelow, otherwise referred to as T1) value of the electron transporting host material is not particularly limited and may be suitably selected in accordance with the intended use. It is, however, preferably 2.2 eV to 3.7 eV, more preferably 2.4 eV to 3.7 eV, still more preferably 2.4 eV to 3.4 eV.

Specific examples of such an electron transporting host material include pyridine, pyrimidine, triazine, imidazole, pyrazole, triazole, oxazole, oxadiazole, fluorenone, anthraquinodimethane, anthrone, diphenylquinone, thiopyrandioxide, carbodiimide, fluorenylidenemethane, distyrylpyrazine, fluorine-substituted aromatic compounds, aromacyclic tetracarboxylic anhydrides of perylene, naphthalene or the like, phthalocyanine, and derivatives thereof (these materials may form a condensed ring with other different rings), metal complexes typified by metal complexes of 8-quinolinol derivatives, metal phthalocyanine, and metal complexes containing benzoxazole, or benzothiazole as the ligand, and the like.

Preferred examples of the electron transporting hosts are metal complexes, azole derivatives (benzimidazole derivatives, imidazopyridine derivatives etc.), and azine derivatives (pyridine derivatives, pyrimidine derivatives, triazine derivatives etc.). Among these, more preferred are metal complex compounds, from the viewpoint of durability. As the metal complex compound, a metal complex containing a ligand having at least one nitrogen atom, oxygen atom, or sulfur atom to be coordinated with the metal is more preferable.

A metal ion in the metal complex is not particularly limited and may be suitably selected in accordance with the intended use. A beryllium ion, a magnesium ion, an aluminum ion, a gallium ion, a zinc ion, an indium ion, a tin ion, a platinum ion, or a palladium ion is preferred; more preferred is a beryllium ion, an aluminum ion, a gallium ion, a zinc ion, a platinum ion, or a palladium ion; and further preferred is an aluminum ion, a zinc ion, a platinum ion or a palladium ion.

Although there are a variety of well-known ligands to be contained in the above-described metal complexes, there may be exemplified ligands described in “Photochemistry and Photophysics of Coordination Compounds” authored by H. Yersin, published by Springer-Verlag Co. in 1987; “YUHKI KINZOKU KAGAKU-KISO TO OUYOU (Organometallic Chemistry-Fundamental and Application)” authored by Akio Yamamoto, published by Shokabo Publishing Co., Ltd. in 1982; and the like.

As the ligands, preferred are nitrogen-containing heterocyclic ligands (these ligands preferably have 1 to 30 carbon atoms, more preferably have 2 to 20 carbon atoms, particularly preferably have 3 to 15 carbon atoms). The ligands may be monodentate ligands or bidentate or higher ligands, but are preferably from bidentate ligands to hexadentate ligands, and mixed ligands of a monodentate ligand with a bidentate to hexadentate ligand are also preferable.

Specific examples of the ligands include azine ligands (e.g. pyridine ligands, bipyridyl ligands, terpyridine ligands, etc.); hydroxyphenylazole ligands (e.g. hydroxyphenyzenzimidazole ligands, hydroxyphenylbenzoxazole ligands, hydroxyphenylimidazole ligands, hydroxyphenylimidazopyridine ligands, etc.); alkoxy ligands (e.g. methoxy, ethoxy, butoxy and 2-ethylhexyloxy ligands, and these ligands preferably have 1 to 30 carbon atoms, more preferably have 1 to 20 carbon atoms, particularly preferably have 1 to 10 carbon atoms); aryloxy ligands (e.g. phenyloxy, 1-naphthyloxy, 2-naphthyloxy, 2,4,6-trimethylphenyloxy, and 4-biphenyloxy ligands, and these ligands preferably have 6 to 30 carbon atoms, more preferably have 6 to 20 carbon atoms, particularly preferably have 6 to 12); heteroaryloxy ligands (e.g. pyridyloxy, pyrazyloxy, pyrimidyloxy, quinolyloxy ligands and the like, and these ligands preferably have 1 to 30 carbon atoms, more preferably have 1 to 20 carbon atoms, and particularly preferably have 1 to 12 carbon atoms); alkylthio ligands (e.g. methylthio, ethylthio ligands and the like, and these ligands preferably have 1 to 30 carbon atoms, more preferably have 1 to 20 carbon atoms, and particularly preferably have 1 to 12 carbon atoms); arylthio ligands (e.g. phenylthio ligands and the like, and these ligands preferably have 6 to 30 carbon atoms, more preferably have 6 to 20 carbon atoms, and particularly preferably have 6 to 12 carbon atoms); heteroarylthio ligands (e.g. pyridylthio, 2-benzimidazolylthio, 2-benzoxazolylthio, 2-benzothiazolylthio ligands and the like, and these ligands preferably have 1 to 30 carbon atoms, more preferably have 1 to 20 carbon atoms, and particularly preferably have 1 to 12 carbon atoms); siloxy ligands (e.g. a triphenylsiloxy group, a triethoxysiloxy group, a triisopropylsiloxy group and the like, and these preferably have 1 to 30 carbon atoms, more preferably have 3 to 25 carbon atoms, and particularly preferably have 6 to 20 carbon atoms); aromatic hydrocarbon anion ligands (e.g. a phenyl anion, a naphthyl anion, an anthranyl anion and the like, and these preferably have 6 to 30 carbon atoms, more preferably have 6 to 25 carbon atoms, and particularly preferably have 6 to 20 carbon atoms); aromatic heterocyclic anion ligands (e.g. a pyrrole anion, a pyrazole anion, a triazole anion, an oxazole anion, a benzoxazole anion, a thiazole anion, a benzothiazole anion, a thiophene anion, a benzothiophene anion and the like, and these preferably have 1 to 30 carbon atoms, more preferably have 2 to 25 carbon atoms, and particularly preferably have 2 to 20 carbon atoms); and indolenine anion ligands. Among these, nitrogen-containing heterocyclic ligands, aryloxy ligands, heteroaryloxy groups, siloxy ligands are preferable. Nitrogen-containing aromatic heterocyclic ligands, aryloxy ligands, siloxy ligands, aromatic hydrocarbon anion ligands, and aromatic heterocyclic anion ligands are more preferable.

Examples of the metal complex electron transporting hosts include compounds described, for example, in Japanese Patent Application Laid-Open (JP-A) Nos. 2002-235076, 2004-214179, 2004-221062, 2004-221065, 2004-221068, and 2004-327313.

Specific examples of such electron transporting host materials include the following materials, but are not limited thereto.

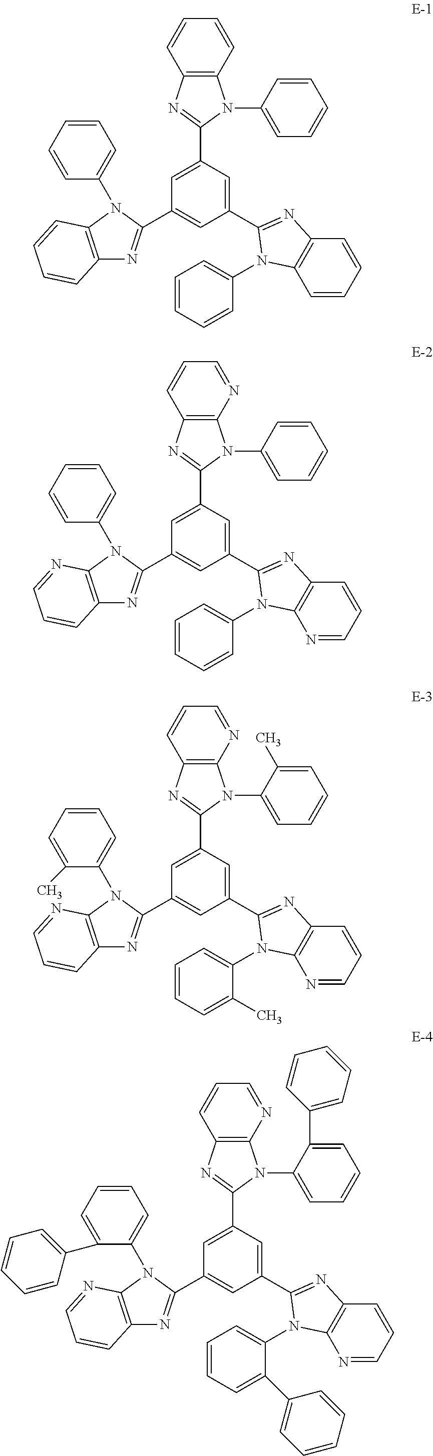

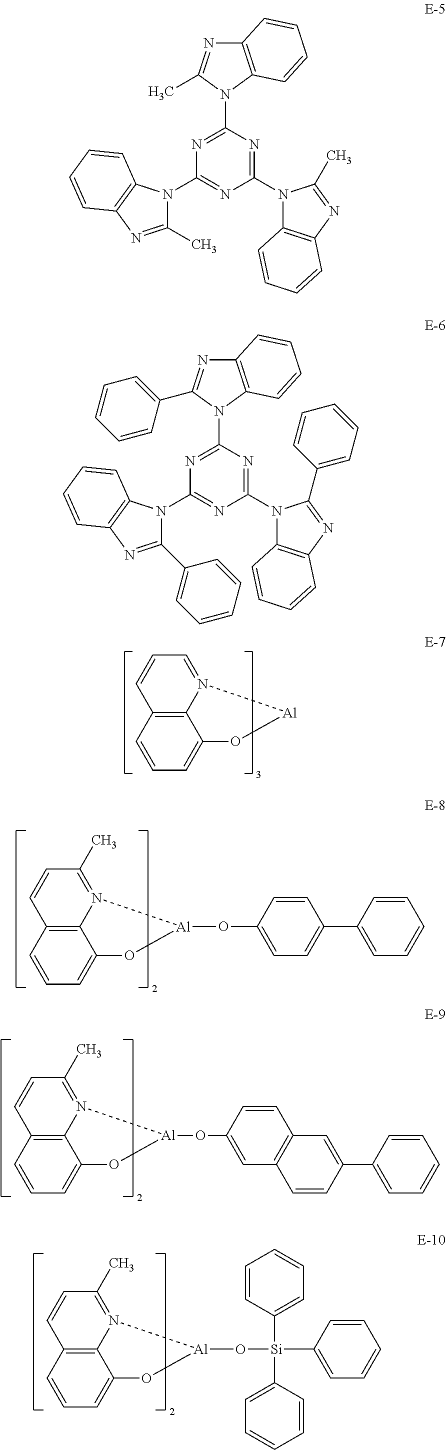

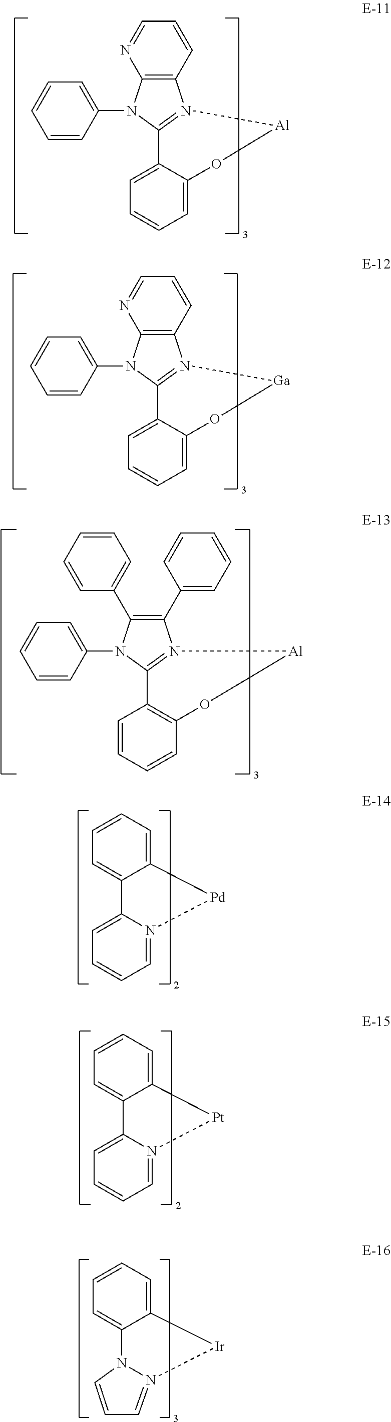

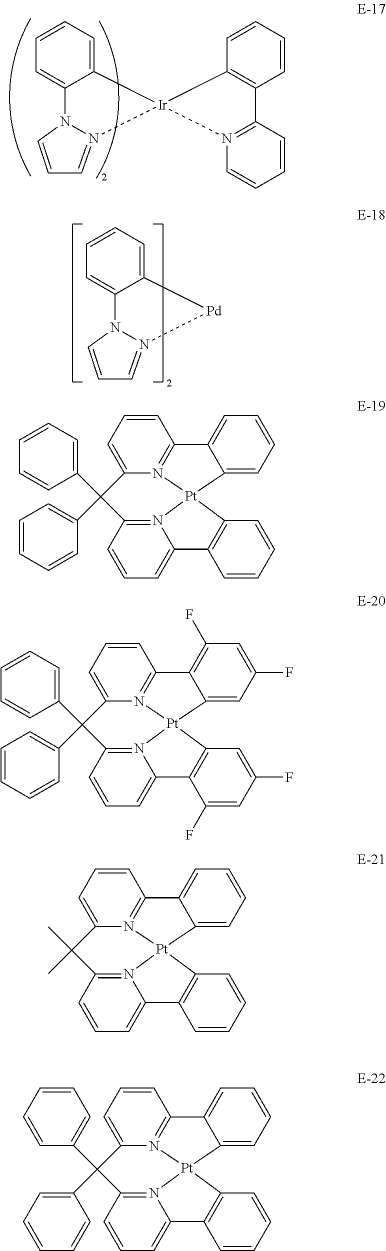

### —Hole Transporting Host Material—

The hole transporting host materials preferably have an ionization potential Ip, from the viewpoint of improvement of durability and reduction in driving electric voltage, of 5.1 eV to 6.4 eV, more preferably 5.4 eV to 6.2 eV, still more preferably 5.6 eV to 6.0 eV. In addition, the hole transporting hosts preferably have an electron affinity Ea, from the viewpoint of improvement of durability and reduction in driving electric voltage, of 1.2 eV to 3.1 eV, more preferably 1.4 eV to 3.0 eV, still more preferably 1.8 eV to 2.8 eV.

The lowest triplet excitation energy (hereinbelow, otherwise referred to as T1) value of the hole transporting host material is not particularly limited and may be suitably selected in accordance with the intended use. It is, however, preferably 2.2 eV to 3.7 eV, more preferably 2.4 eV to 3.7 eV, still more preferably 2.4 eV to 3.4 eV.

Specific examples of the hole transporting host materials include pyrrole, indole, carbazole, azaindole, azacarbazole, triazole, oxazole, oxadiazole, pyrazole, imidazole, thiophene, polyarylalkane, pyrazoline, pyrazolone, phenylenediamine, arylamine, amino-substituted chalcone, styrylanthracene, fluorenone, hydrazone, stilbene, silazane, aromatic tertiary amine compounds, styrylamine compounds, aromatic dimethylidine compounds, porphyrin compounds, polysilane compounds, poly(N-vinylcarbazole), aniline copolymers, electrically conductive high-molecular oligomers such as thiophene oligomers, polythiophenes and the like, organic silanes, carbon films, derivatives thereof.

Among these, preferred are indole derivatives, carbazole derivatives, azaindole derivatives, azacarbazole derivatives, aromatic tertiary amine compounds and thiophene derivatives. Particularly preferred are compounds having a plurality of indole skeletons, carbazole skeletons, azaindole skeletons, azacarbazole skeletons or aromatic tertiary amine skeletons in their molecules.

Furthermore, in the present invention, it is possible to use a host material where part of or all of hydrogen is substituted with heavy hydrogen (see Patent Application Laid-Open (JP-A) No. 2008-126130, and Japanese Patent Application Publication (JP-B) No. 2004-515506).

Specific examples of such hole transporting host material include the following compounds, but are not limited thereto.

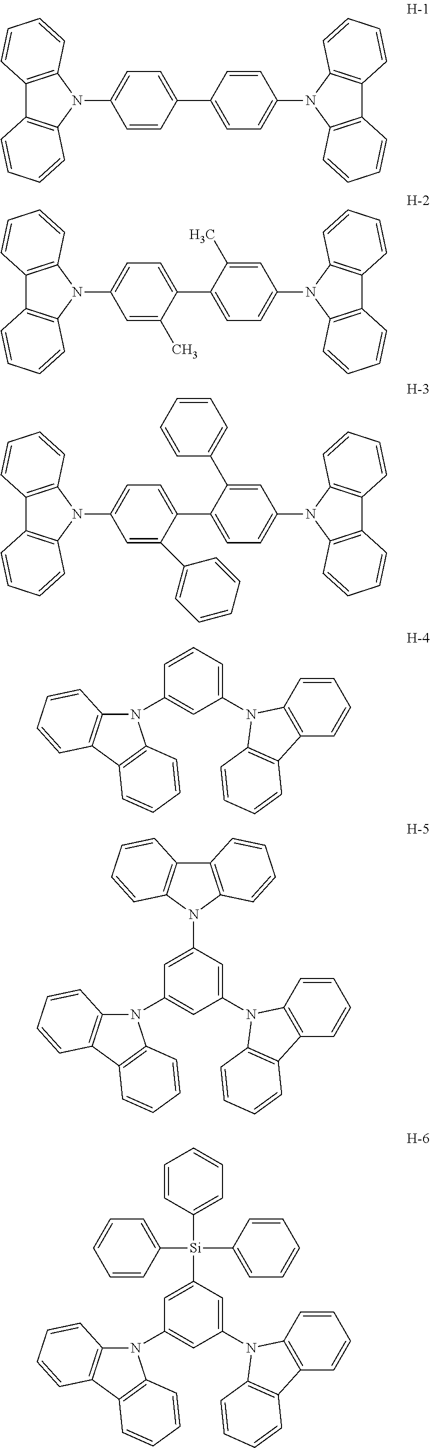

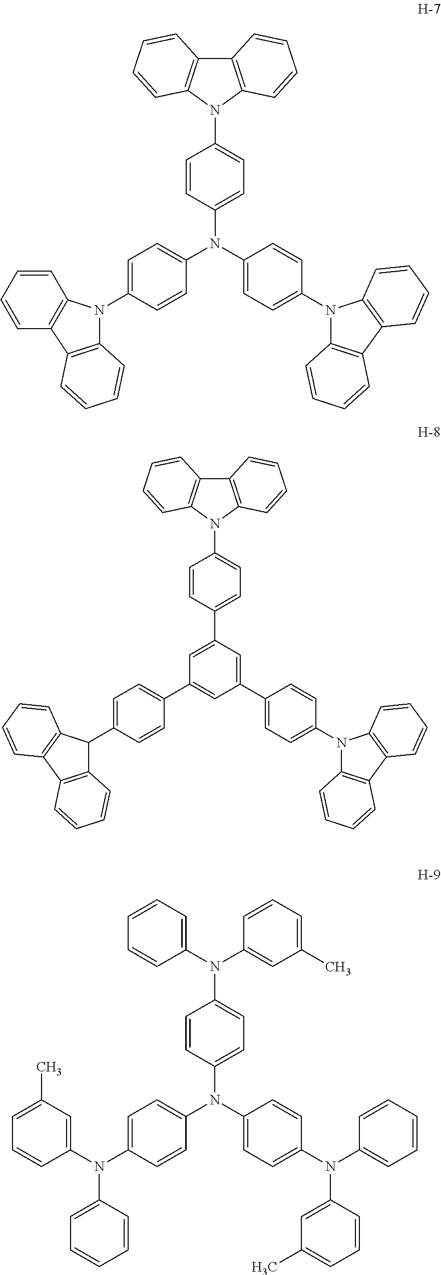

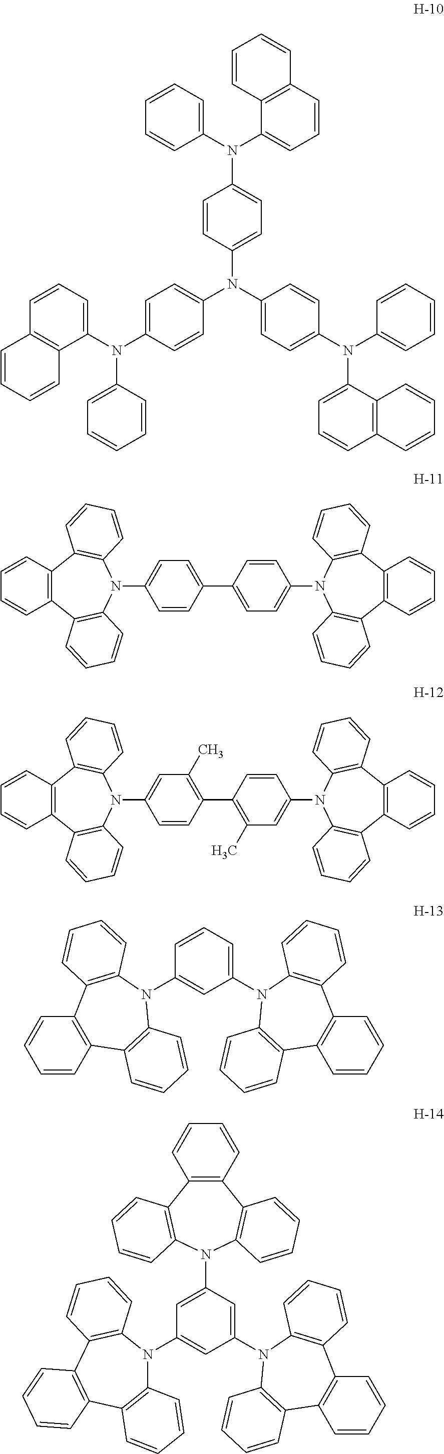

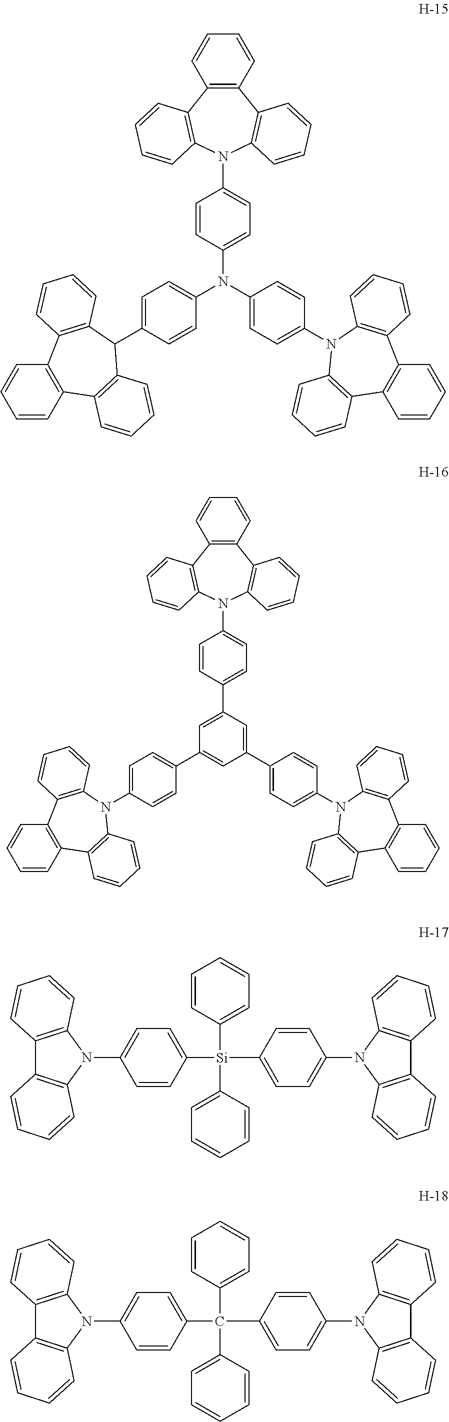

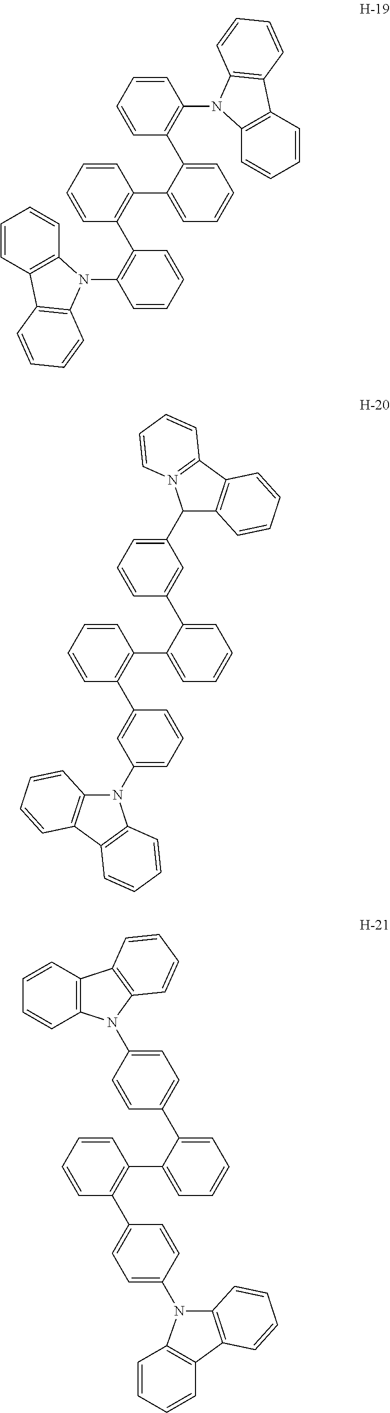

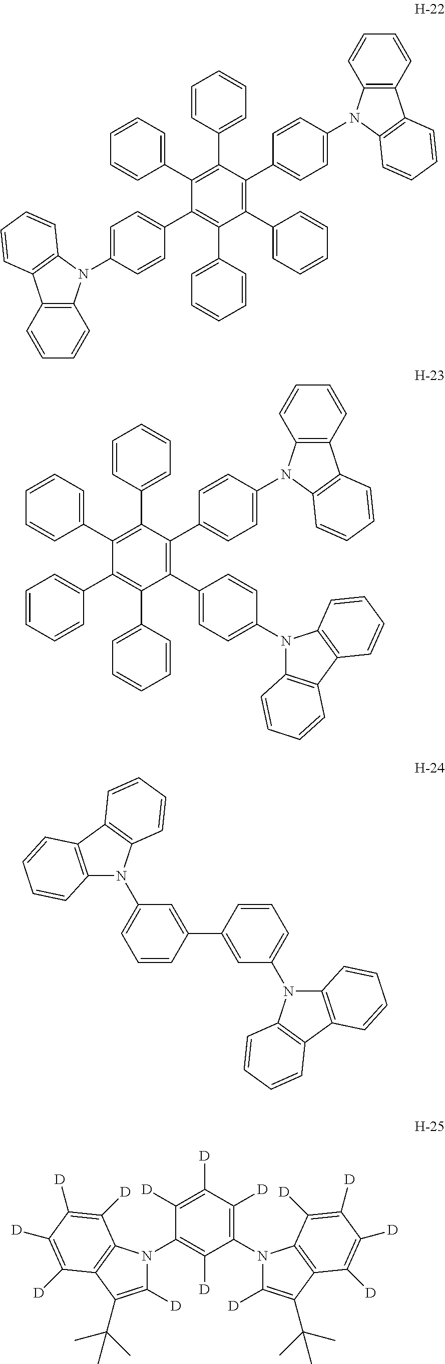

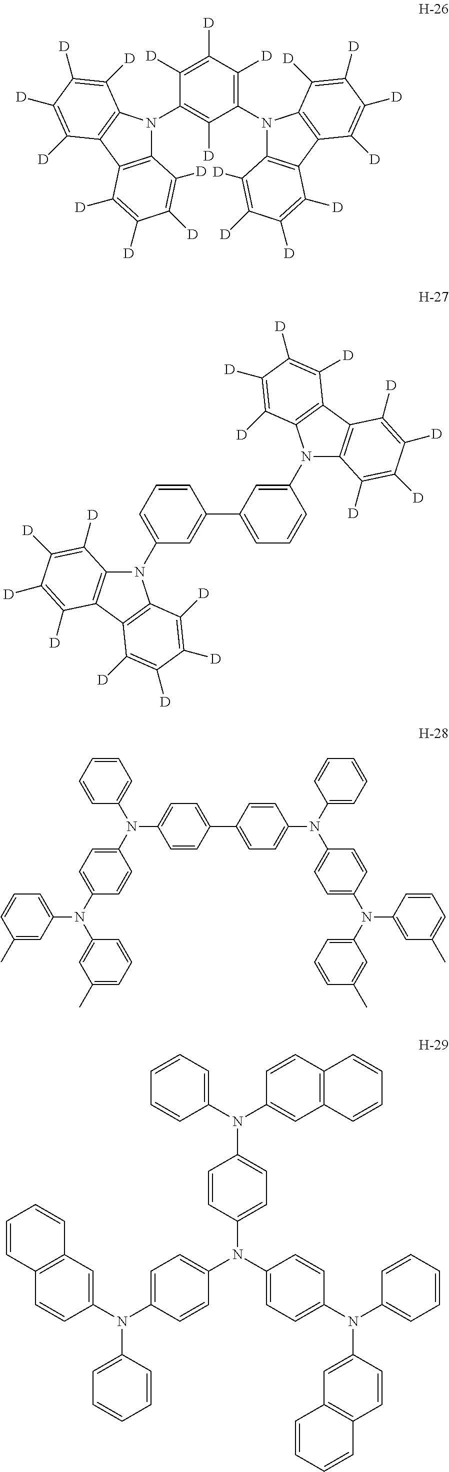

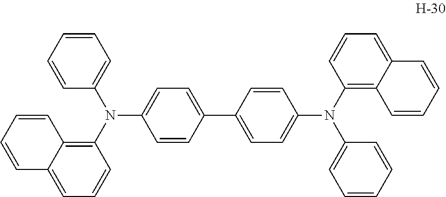

The organic electroluminescence element of the present invention includes an anode, a cathode, and at least one organic layer which includes a light emitting layer, and which is provided between the anode and the cathode, and may further other layers as required.

The organic layer includes at least the light emitting layer, may include an electron transporting layer, an electron injection layer, and may further include a hole injection layer, a hole transporting layer, a hole blocking layer, an electron blocking layer, and the like.

### <Hole Injection Layer and Hole Transporting Layer>

The hole injection layer and the hole transporting layer are layers having a function to receive holes from an anode or from an anode side and to transport the holes to a cathode side. The hole injection layer and the hole transporting layer may take a single layer structure or a multilayer structure composed of plural layers of a homogeneous composition or a heterogeneous composition.

A hole injection material or hole transporting material for use in these layers may be low-molecular weight compounds or high-molecular weight compounds.

The low-molecular weight compound or high-molecular weight compound is not particularly limited and may be suitably selected in accordance with the intended use. Specific examples thereof include pyrrole derivatives, carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidyne compounds, phthalocyanine compounds, porphyrin compounds, thiophene compounds, organic silane derivatives, and carbon. These may be used alone or in combination.

An electron-accepting dopant may be incorporated into the hole injection layer and the hole transporting layer in the organic EL element of the present invention.

As the electron-accepting dopant to be incorporated into the hole injection layer and the hole transporting layer, either or both of an inorganic compound or an organic compound may be used as long as the compound has electron accepting property and a property for oxidizing an organic compound.

The inorganic compound is not particularly limited and may be suitably selected in accordance with the intended use. For example, metal halides, such as iron (II) chloride, aluminum chloride, gallium chloride, indium chloride and antimony pentachloride, and metal oxides, such as vanadium pentaoxide, and molybdenum trioxide are exemplified.

The organic compound is not particularly limited and may be suitably selected in accordance with the intended use. For example, compounds having a substituent such as a nitro group, a halogen, a cyano group, a trifluoromethyl group or the like; quinone compounds; acid anhydride compounds; and fullerenes are exemplified.

These electron-accepting dopants may be used alone or in combination.

The amount of use of the electron-accepting dopant varies depending on the type of material, however, it is preferably 0.01% by mass to 50% by mass, more preferably 0.05% by mass to 20% by mass, still more preferably 0.1% by mass to 10% by mass, with respect to the hole transporting layer material or hole injecting material.

The hole injection layer and the hole transporting layer can be formed by a known method, and can be suitably formed, for example, by a dry film-forming method such as a vapor deposition method and a sputtering method; a wet-process coating method, a transfer method, a printing method, and an inkjet method.

The thickness of the hole injection layer and hole transporting layer is preferably 1 nm to 500 nm, more preferably 5 nm to 200 nm, still more preferably 10 nm to 100 nm.

### <Hole Blocking Layer and Electron Blocking Layer>

The hole blocking layer is a layer having a function to prevent holes transported from the anode side to the light emitting layer from passing through the cathode side. The hole blocking layer is usually provided as an organic layer contiguous to the light emitting layer on the cathode side.

The electron blocking layer is a layer having a function to prevent electrons transported from the cathode side to the light emitting layer from passing through the anode side. The electron blocking layer is usually provided as an organic layer contiguous to the light emitting layer on the anode side.

As a compound constituting the hole blocking layer, for example, aluminum complexes such as BAlq, triazole derivatives, and phenanthroline derivatives such as BCP are exemplified.

As a compound constituting the electron blocking layer, for example, those exemplified as hole transporting materials above can be used.

The method of forming the electron blocking layer and hole blocking layer is not particularly limited. These layers can be formed by a known method, and can be suitably formed, for example, by a dry film-forming method such as a vapor deposition method and a sputtering method; a wet-process coating method, a transfer method, a printing method, and an inkjet method.

The thickness of the hole blocking layer and the electron blocking layer is preferably 1 nm to 200 nm, more preferably 1 nm to 50 nm, still more preferably 3 nm to 10 nm. The hole blocking layer and the electron blocking layer may take a single layer structure composed of one or two or more of the above-mentioned materials or a multilayer structure composed of plural layers of a homogeneous composition or a heterogeneous composition.

### <Electrode>

The organic electroluminescence element of the present invention includes a pair of electrodes, i.e., an anode and a cathode. In terms of properties of the organic electroluminescence element, at least one of the anode and the cathode is preferably transparent. The anode is generally sufficient to have the function of an electrode to supply holes to the organic compound layer. The cathode is generally sufficient to have the function of an electrode to inject electrons into the organic compound layer.

The shape, structure, and size of the electrodes are not particularly limited, and these may be suitably selected from known materials of electrode in accordance with the application and purpose of the organic electroluminescence element.

As a material constituting the electrodes, for example, metals, alloys, metal oxides, electrically conductive compounds or mixtures thereof are preferably exemplified.

### —Anode—

Specific examples of the material constituting the anode include tin oxides doped with antimony, fluorine, etc. (ATO, FTO); electrically conductive metal oxides such as tin oxide, zinc oxide, indium oxide, indium tin oxide (ITO), and indium zinc oxide (IZO); metals such as gold, silver, chromium, and nickel, mixtures and laminates of these metals with electrically conductive metal oxides; inorganic electrically conductive materials such as copper iodide, and copper sulfide; organic electrically conductive materials such as polyaniline, polythiophene, and polypyrrole, and laminates of these organic electrically conductive materials with ITO, etc. Among these materials, preferred are electrically conductive metal oxides, and ITO is especially preferred from the viewpoint of productivity, high-conductivity, transparency and the like.

### —Cathode—

Specific examples of the material constituting the cathode include alkali metals (e.g. Li, Na, K, Cs, etc.), alkaline earth metals (e.g. Mg, Ca, etc.), and rare earth metals such as gold, silver, lead, aluminum, sodium-potassium alloy, lithium-aluminum alloy, magnesium-silver alloy, indium, and ytterbium. These materials may be used alone, however, from the viewpoint of simultaneous achievement of stability and electron injecting property, two or more materials can be preferably used in combination.

Among these, as the material constituting the cathode, alkali metals and alkaline earth metals are preferred in terms of the electron injecting property, and materials mainly containing aluminum are preferred for their excellent storage stability.

The materials mainly containing aluminum mean aluminum alone, alloys of aluminum with 0.01% by mass to 10% by mass of alkali metal or alkaline earth metal, or mixtures of these (e.g., lithium-aluminum alloy, magnesium-aluminum alloy, etc.).

The electrodes can be formed by known methods with no particular limitation. For example, the electrodes can be formed according to a method arbitrarily selected from among wet-process methods such as a printing method, and a coating method; physical methods such as a vacuum vapor deposition method, a sputtering method, and an ion-plating method; and chemical methods such as a CVD method, and a plasma CVD method, taking the suitability with the material constituting the electrodes in consideration. For example, in the case of selecting ITO as the material of the anode, the anode can be formed according to a direct current or high-frequency sputtering method, a vacuum vapor deposition method, an ion-plating method, etc. In the case of selecting metals as the materials of the cathode, the cathode can be formed with one or two or more kinds of the materials at the same time or in order by a sputtering method, etc.

In the formation of the electrodes, patterning of the electrode may be carried out by chemical etching such as photo-lithography, may be carried out by physical etching with use of a laser, etc., may be carried out by vacuum vapor deposition or sputtering on a superposed mask, or a lift-off method or a printing method may be used.

### <Substrate>

The organic electroluminescence element of the present invention is preferably disposed on a substrate, may be disposed in the form where the electrode is contiguous to a substrate or may be disposed, via an intermediate layer, over a substrate.

The material of the substrate is not particularly limited and may be suitably selected in accordance with the intended use. Specific examples of materials of the substrate include inorganic materials, e.g., yttria stabilized zirconia (YSZ), glass (e.g., alkali-free glass, soda-lime glass, etc.), and organic materials, such as polyester (e.g., polyethylene terephthalate, polybutylene phthalate, polyethylene naphthalate, etc.), polystyrene, polycarbonate, polyether sulfone, polyallylate, polyimide, polycycloolefin, norbornene resin, poly(chlorotrifluoroethylene), etc.

The shape, structure and size of the substrate are not particularly limited, and these can be arbitrarily selected in accordance with the intended use and purpose of the light emitting element. In general, the substrate is preferably plate-shaped. The structure of the substrate may be a single layer structure or may be a laminated structure, and may consist of a single member or may be formed of two or more members. The substrate may be transparent or opaque. When a transparent substrate is used, the substrate may be colorless and transparent, or may be colored and transparent.

A moisture-proof layer (gas barrier layer) can be disposed on a surface or a back surface of the substrate.

Examples of the material of the moisture-proof layer (gas barrier layer) include inorganic materials such as silicon nitride, and silicon oxide.

The moisture-proof layer (gas barrier layer) can be formed by, for example, a high-frequency sputtering method.

### —Protective Layer—

The entirety of the organic electroluminescence element may be protected with a protective layer.

The materials contained in the protective layer are not particularly limited and may be suitably selected in accordance with the intended use, as long as they have a function to prevent substances accelerating degradation of the element, such as moisture and oxygen, from entering the element. Specific examples of the materials of the protective layer include metals such as metals (e.g., In, Sn, Pb, Au, Cu, Ag, Al, Ti, Ni, etc.); metal oxides (e.g., MgO, SiO, SiO₂, Al₂O₃, GeO, NiO, CaO, BaO, Fe₂O₃, Y₂O₃, TiO₂, etc.); metal nitrides (e.g. SiNx, SiNxOy, etc.); metal fluorides (e.g. MgF₂, LiF, AlF₃, CaF₂, etc.); copolymers of dichlorodifluoroethylene with polyethylene, polypropylene, polymethylmethacrylate, polyimide, polyurea, polytetrafluoroethylene, polychlorotrifluoroethylene, polydichlorodifluoroethylene or dichlorodifluoroethylene; a copolymer obtainable by copolymerization of tetrafluoroethylene with a monomer mixture containing at least one comonomer; a fluorine-containing copolymer having a cyclic structure at its copolymerized main chain; water absorbing materials having a water absorption of 1% or more, and moisture-proof materials having a water absorption of 0.1% or less.

The method of forming the protective layer is not particularly limited and may be suitably selected in accordance with the intended use. For example, there are exemplified a vacuum deposition method, sputtering method, reactive sputtering method, MBE (Molecular Beam epitaxy) method, cluster ion beam method, ion plating method, plasma polymerization method (high-frequency excited ion plating method), plasma CVD method, laser CVD method, thermal CVD method, gas-source CVD method, coating method, printing method, and transfer method.

### —Sealing Container—

The entirety of the organic electroluminescence element of the present invention may be sealed using a searing container. Further, a water absorber or an inert liquid may be sealed in a space between the sealing container and the organic electroluminescence element.

The water absorber is not particularly limited and may be suitably selected in accordance with the intended use. Specific examples thereof include barium oxide, sodium oxide, potassium oxide, calcium oxide, sodium sulfate, calcium sulfate, magnesium sulfate, phosphorus pentoxide, calcium chloride, magnesium chloride, copper chloride, cesium fluoride, niobium fluoride, calcium bromide, vanadium bromide, molecular sieve, zeolite, magnesium oxide and the like.

The inert liquid is not particularly limited and may be suitably selected in accordance with the intended use. Specific examples thereof include paraffins, liquid paraffins; fluorine solvents such as perfluoroalkane, perfluoroamine, and perfluoroether; chlorine solvents, and silicone oils.

### —Resin Sealing Layer—

In the organic electroluminescence element of the present invention, it is preferred that the degradation in performance of the element due to oxygen and moisture in the air be prevented by sealing with a resin sealing layer.

A resin material for use in the resin sealing layer is not particularly limited and may be suitably selected in accordance with the intended use. For example, acrylic resins, epoxy resins, fluorochemical resins, silicone resins, rubber resins, and ester resins are exemplified. Among these, epoxy resins are particularly preferred from the viewpoint of their excellence in water-proof function. Among the epoxy resins, preferred are thermocurable epoxy resins or photo-curable epoxy resins.

The method of forming the resin sealing layer is not particularly limited and may be suitably selected in accordance with the intended use. For instance, there are exemplified a method of coating a resin solution, a method of bonding or thermally bonding a resin sheet, and a dry-process polymerization method through vapor evaporation, sputtering, or the like.

### —Sealing Adhesive—

A searing adhesive for use in the present invention has a function to prevent moisture and oxygen from entering from the ends of the organic electroluminescence element.

As the material of the sealing adhesive, the same material as used for the resin sealing layer can be used. Among these materials, epoxy resin adhesives are preferred from the viewpoint of water-proof, with a photocurable adhesive or a thermocurable adhesive being particularly preferable.

Also, it is preferable to add a filler in the sealing adhesive. As the filler, for example, inorganic materials such as SiO₂, SiO (silicon oxide), SiON (silicon oxynitride), and SiN (silicon nitride) are preferred. By addition of the filler, the viscosity of the sealing adhesive is increased, leading to improvement in processability and resistance to moisture.

The sealing adhesive may contain a desiccating agent. As the desiccating agent, for example, a barium oxide, a calcium oxide and a strontium oxide are exemplified. The addition amount of the desiccating agent is preferably 0.01% by mass to 20% by mass, more preferably 0.05% by mass to 15% by mass with respect to the amount of the sealing adhesive. When the addition amount is less than 0.01% by mass, the effect of adding the desiccating agent may decrease. When the addition is more than 20% by mass, it may be difficult to uniformly disperse the desiccating agent in the searing adhesive.

In the present invention, the sealing adhesive containing a desiccating agent is applied in a predetermined amount onto a laminate of the organic electroluminescence element by a dispenser or the like. After the coating, a second substrate is stacked on the laminate, and the sealing adhesive is cured, thereby the organic electroluminescence element can be sealed.

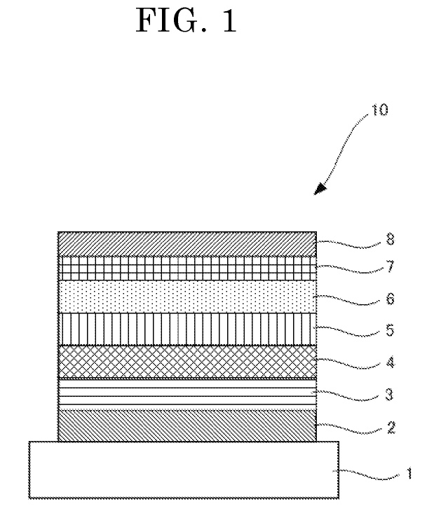

FIG. 1 is a schematic diagram illustrating an example of a layer configuration of an organic electroluminescence element according to the present invention. An organic EL element 10 has a layer configuration where an anode 2 (e.g., ITO electrode) formed on a glass substrate 1, a hole injection layer 3, a hole transporting layer 4, a light emitting layer 5, an electron transporting layer 6, an electron injection layer 7, and a cathode 8 (e.g., Al—Li electrode) are laminated in this order. Note that the anode 2 (e.g., ITO electrode) and the cathode 8 (e.g., Al—Li electrode) are connected to each other via a power source.

### —Driving—

By the application of DC (if necessary, AC component may be contained) voltage (generally from 2 volts to 15 volts) between the anode and the cathode, or by the application of DC electric current, light emission of the organic electroluminescence element of the invention can be obtained.

The organic electroluminescence element of the present invention can be applied for an active matrix through use of a thin-film transistor (TFT). As an active layer of a thin-film transistor, an amorphous silicon, a high-temperature polysilicon, a low-temperature polysilicon, a micro-crystal silicon, an oxide semiconductor, an organic semiconductor, a carbon nano-tube or the like can be used.

In the organic electroluminescence element of the present invention, thin-film transistors described, for example, in WO2005/088726, Japanese Patent Application Laid-Open (JP-A) No. 2006-165529, U.S. Patent Application No. 200810237598A1 can be applied.

The method of improving the light extraction efficiency of the organic electroluminescence element is not particularly limited, and the light extraction efficiency can be improved by various known contrivance. For instance, the light extraction efficiency can be improved by subjecting a substrate surface to a surface process (e.g., a microscopic concave-convex pattern is formed), or by controlling the refractive indices of a substrate, an ITO layer and organic layer(s), or by adjusting the thickness of a substrate, an ITO layer and organic layer(s), thereby making it possible to improve the external quantum efficiency.

The method of extracting light from the organic electroluminescence element of the present invention may be top-emission mode or bottom-emission mode.

The organic electroluminescence element of the present invention may have a resonator structure. For example, the organic electroluminescence element has a multilayer film mirror including a plurality of laminated films different in refractive index, a transparent or translucent electrode, a light emitting layer, and a metal electrode by superposition on a transparent substrate. The light generated from the light emitting layer repeats reflection and resonates between the multilayer film mirror and the metal electrode as reflectors.

As another preferred embodiment, a transparent or translucent electrode and a metal electrode respectively function as reflectors on a transparent substrate, and light generated from the light emitting layer repeats reflection and resonates between them.

To form a resonance structure, effective refractive indices of two reflectors, optical path determined by the refractive index and thickness of each layer between the reflectors are adjusted to be optimal values to obtain a desired resonance wavelength. The expression of the case of the first embodiment is disclosed in Japanese Patent Application Laid-Open (JP-A) No. 09-180883. The expression of the case of the second embodiment is disclosed in Japanese Patent Application Laid-Open (JP-A) No. 2004-127795.

### —Application—

The application of the organic electroluminescence element of the present invention is not particularly limited and maybe arbitrarily selected in accordance with the intended use. For example, the organic electroluminescence element of the present invention can be suitably used for display elements, displays, backlights, electrophotography, light sources for illumination, light sources for recording, light sources for exposure, light sources for reading, signs, sign boards, interiors, and optical communications.

The organic EL display can be made a full color type by a known method as described in Monthly Display, September issue, pp. 33-37 (2000), for example, there are known the three color light emitting method wherein three organic EL elements which respectively emit lights corresponding to the three primary colors (blue (B), green (G), red (R)) are placed on a substrate; the white light method wherein a white light from an organic EL element for white light emission is divided into the three primary colors via color filters; and the color conversion method wherein a blue light emitted from an organic EL element for blue light emission is converted into red (R) and green (G) via a fluorescent pigment layer. A flat type light source emitting lights of desired colors can be provided by using a plurality of the organic EL elements different in emission color and obtainable by any of the above-described methods. Such a light source is, for example, a white light emitting light source using a blue luminescence element and a yellow luminescence element in combination, and a white light emitting light source using a blue luminescence element, a green luminescence element, and a red luminescence.

### EXAMPLES

Hereinafter, the present invention will be further described in detail with reference to Examples of the present invention, however, the present invention shall not be construed as being limited thereto.

### Comparative Example 1

### Production of Organic Electroluminescence Element

A glass substrate of 0.5 mm in thickness and 2.5 cm in square was placed in a cleaning vessel to be subjected to ultrasonic cleaning with 2-propanol, and then subjected to UV ozone treatment for 30 minutes. Over the glass substrate, each of the following layers was deposited by vacuum deposition method. Note that the deposition rate employed in the following Examples and Comparative Examples is 0.2 nm/sec unless otherwise specified. The deposition rate was measured using a crystal oscillator. Also, the thickness of each of the following layers was measured using the crystal oscillator.

First, on the glass substrate, an ITO (Indium Tin Oxide) was deposited, as an anode, in thickness of 100 nm by sputtering deposition.

Next, on the anode (ITO), 2-TNATA (4,4′,4″-Tris(N-(2-naphtyl)-N-phenyl-amino)-triphenylamine) was deposited, as a hole injection layer, in thickness of 140 nm.

Next, on the hole injection layer, α-NPD (Bis[N-(1-naphthyl)-N-pheny]benzidine) was deposited, as a hole transporting layer, in thickness of 7 nm.

Next, on the hole transporting layer, Amine Compound 1 represented by the following structural formula was deposited, as a second hole transporting layer, in thickness of 3 nm.

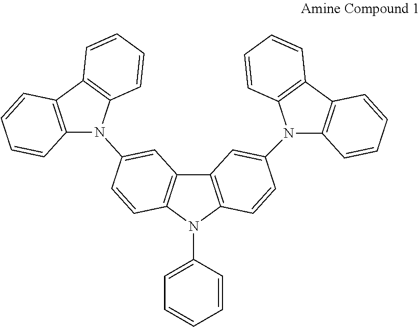

Subsequently, on the second hole transporting layer, a light emitting layer was deposited in thickness of 30 nm, in which 6.0% by mass of IR (ppy)₃ tris(2-phenylpyridine)iridium(III)), as a hole transporting phosphorescence emitting material, represented by the following structural formula was doped with respect to mCP (N,N′-dicarbazolyl-3,5-benzene) represented by the following structural formula H-4 as a hole transporting host material.

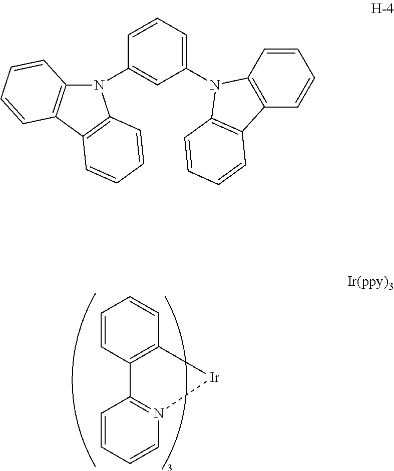

Next, on the light emitting layer, BAlq (Bis-(2-methyl-8-quinolinolato)-4-(phenyl-phenolate)-aluminum-(III)) was deposited, as an electron transporting layer, in thickness of 40 nm.

Next, on the electron transporting layer, LiF was deposited, as an electron injection layer, in thickness of 1 nm.

Next, as a cathode, a patterned mask (a mask having a light emitting region of 2 mm×2 mm) was placed on the electron injection layer, and metal aluminum was deposited thereover so as to have a thickness of 100 nm, thereby producing a laminate.

The laminate produced in the above procedure was placed in a glove box replaced with argon gas, and the glove box was sealed using a stainless sealing can and a ultraviolet ray-curable type adhesive (XNR5516HV, produced by Nagase-Ciba Co., Ltd.), thereby an organic electroluminescence element of Comparative Example 1 was produced.

### Comparative Examples 2 to 24, Examples 1 to 6 and 10 to 17

### Production of Organic Electroluminescence Element

Organic electroluminescence elements of Comparative Examples 2 to 24 and Examples 1 to 6 and 10 to 17 were produced in the same manner as in Comparative Example 1, except that the light emitting material and the electron transporting material (for use in electron transporting layer) were changed to those described in Tables 1A and 1B.

TABLE 1A

| | Light | Electron |
|---|---|---|
| | emitting | transporting |
| | material | material |
| Comp. | Ir(ppp)₃ | Balq |
| Ex. 1 | | |
| Comp. | Ir(ppp)₃ | Nitrogen- |
| Ex. 2 | | containing |
| | | heterocyclic |
| | | derivative 1 |
| Comp. | Ir(ppp)₃ | Nitrogen- |
| Ex. 3 | | containing |
| | | heterocyclic |
| | | derivative 2 |
| Comp. | FIrpic | Balq |
| Ex. 4 | | |
| Comp. | FIrpic | Nitrogen- |
| Ex. 5 | | containing |
| | | heterocyclic |
| | | derivative 3 |
| Comp. | FIrpic | Nitrogen- |
| Ex. 6 | | containing |
| | | heterocyclic |
| | | derivative 4 |
| Comp. | Light | Balq |
| Ex. 7 | emitting | |
| | material A | |
| Comp. | Light | Nitrogen- |
| Ex. 8 | emitting | containing |
| | material A | heterocyclic |
| | | derivative 1 |
| Comp. | Light | Nitrogen- |
| Ex. 9 | emitting | containing |
| | material A | heterocyclic |
| | | derivative 3 |
| Comp. | Compound | Balq |
| Ex. 10 | (I-24) | |
| Comp. | Compound | Alq |
| Ex. 11 | (I-24) | |
| Comp. | Compound | Balq |
| Ex. 12 | (I-26) | |
| Comp. | Compound | Balq |
| Ex. 13 | (I-15) | |
| Comp. | Compound | Alq |
| Ex. 14 | (I-15) | |
| Comp. | Compound | Balq |
| Ex. 15 | (I-16) | |
| Comp. | Compound | Balq |
| Ex. 16 | (I-20) | |
| Comp. | Compound | Balq |
| Ex. 17 | (I-5) | |

TABLE 1B

| | Light | Electron |
|---|---|---|
| | emitting | transporting |
| | material | material |
| Ex. 1 | Compound | Nitrogen- |
| | (I-24) | containing |
| | | heterocyclic |
| | | derivative 1 |
| Ex. 2 | Compound | Nitrogen- |
| | (I-24) | containing |
| | | heterocyclic |
| | | derivative 2 |
| Ex. 3 | Compound | Nitrogen- |
| | (I-24) | containing |
| | | heterocyclic |
| | | derivative 3 |
| Ex. 4 | Compound | Nitrogen- |
| | (I-26) | containing |
| | | heterocyclic |
| | | derivative 2 |
| Ex. 5 | Compound | Nitrogen- |
| | (I-26) | containing |
| | | heterocyclic |
| | | derivative 3 |
| Ex. 6 | Compound | Nitrogen- |
| | (I-26) | containing |
| | | heterocyclic |
| | | derivative 4 |
| Comp. | Compound | Nitrogen- |
| Ex. 18 | (I-15) | containing |
| | | heterocyclic |
| | | derivative 1 |
| Comp. | Compound | Nitrogen- |
| Ex. 19 | (I-15) | containing |
| | | heterocyclic |
| | | derivative 2 |
| Comp. | Compound | Nitrogen- |
| Ex. 20 | (I-15) | containing |
| | | heterocyclic |
| | | derivative 3 |
| Ex. 10 | Compound | Nitrogen- |
| | (I-16) | containing |
| | | heterocyclic |
| | | derivative 2 |
| Ex. 11 | Compound | Nitrogen- |
| | (I-16) | containing |
| | | heterocyclic |
| | | derivative 3 |
| Ex. 12 | Compound | Nitrogen- |
| | (I-16) | containing |
| | | heterocyclic |
| | | derivative 4 |
| Ex. 13 | Compound | Nitrogen- |
| | (I-20) | containing |
| | | heterocyclic |
| | | derivative 1 |
| Ex. 14 | Compound | Nitrogen- |
| | (I-20) | containing |
| | | heterocyclic |
| | | derivative 2 |
| Ex. 15 | Compound | Nitrogen- |
| | (I-20) | containing |
| | | heterocyclic |
| | | derivative 3 |
| Comp. | Compound | Nitrogen- |
| Ex. 21 | (I-5) | containing |
| | | heterocyclic |
| | | derivative 2 |
| Comp. | Compound | Nitrogen- |
| Ex. 22 | (I-5) | containing |
| | | heterocyclic |
| | | derivative 3 |
| Comp. | Compound | Nitrogen- |
| Ex. 23 | (I-5) | containing |
| | | heterocyclic |
| | | derivative 4 |
| Comp. | Compound | Balq |
| Ex. 24 | (I-4) | |
| Ex. 16 | Compound | Nitrogen- |
| | (I-4) | containing |
| | | heterocyclic |
| | | derivative 1 |
| Ex. 17 | Compound | Nitrogen- |
| | (I-4) | containing |
| | | heterocyclic |
| | | derivative 3 |

In Tables 1A and 1B, “Alq” means Tris(8-hydroxyquinolinato)aluminum(III). The following designates each of the structural formula of FIrpic, Light emitting material A, Compound (I-24), Compound (I-26), Compound (I-15), Compound (I-16), Compound (I-20), Compound (I-5), Compound (I-4), and Nitrogen-containing heterocyclic derivatives 1 to 4.

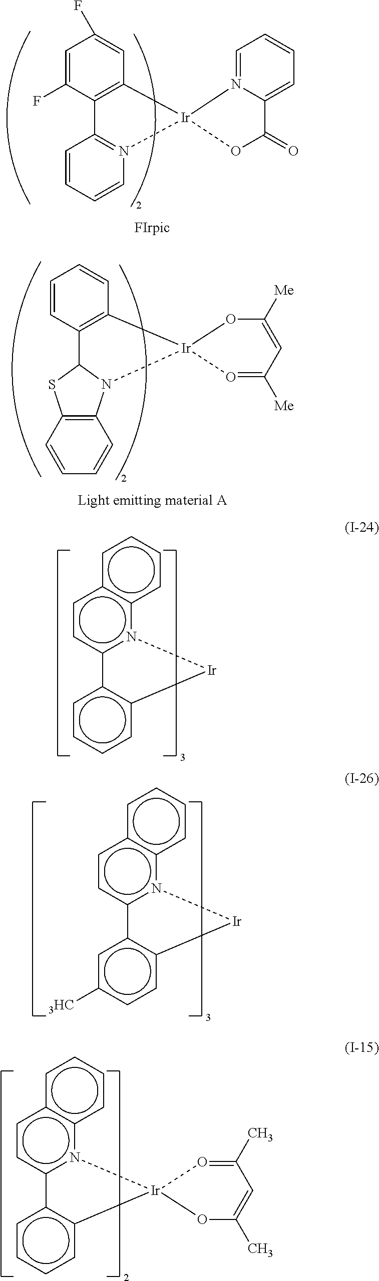

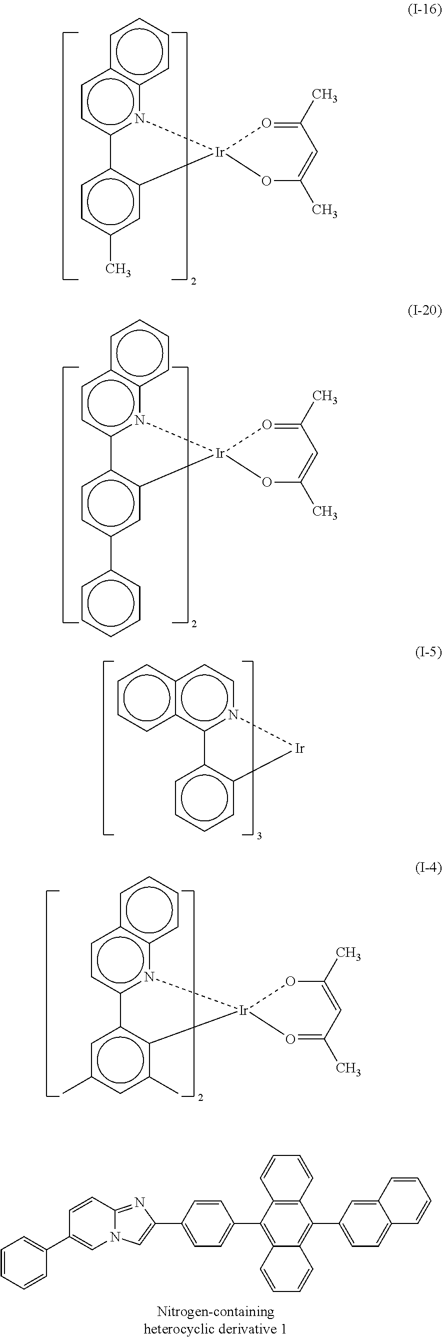

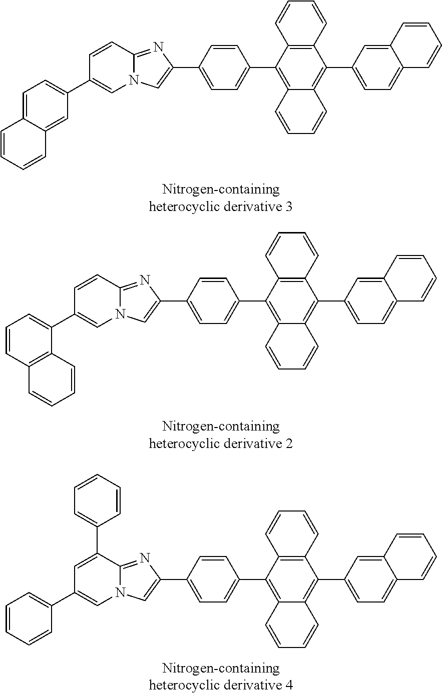

Next, each of the produced organic electroluminescence elements of Examples 1 to 6 and 10 to 17 and Comparative Examples 1 to 24, the external quantum efficiency and the time required to reach one-half of the maximum luminescence intensity were measured.

### <Measurement of External Quantum Efficiency>

A direct voltage was applied to each of the elements using SOURCE MEASURE UNIT 2400 manufactured by Toyo Corporation so as to make it emit light. The light emission spectrum/luminescence were measured using a spectrum analyzer SR-3 manufactured by TOPCON Corporation. Based on the measured values, the external quantum efficiency under application of a current in 10 mA/cm² was calculated through luminescence conversion. The results are shown in Tables 2 to 11.

Note that in Table 2, Comparative Example 1 was used as a standard; in Table 3, Comparative Example 4 was used a standard; in Table 4, Comparative Example 7 was used as a standard; in Table 5, Comparative Example 10 was used as a standard; in Table 6, Comparative Example 12 was used as a standard; in Table 7, Comparative Example 13 was used as a standard; in Table 8, Comparative Example 15 was used a standard; in Table 9, Comparative Example 16 was used as a standard; in Table 10, Comparative Example 17 was used as a standard, and in Table 11, Comparative Example 24 was used as a standard. Regarding organic electroluminescence elements of Examples and Comparative Examples other than those used as standard, a relative value determined when the value of external quantum efficiency of the standard Comparative Example is regarded as “100”.

### <Measurement of Time Required to Reach One-Half of Maximum Luminescence Intensity>

A direct voltage was applied to each of the elements so as to have a luminescence intensity of 1,000 cd/m², and the time required for the luminescence intensity to reach 500 cd/m² while continuously driving the electric voltage thereto. The results are shown in Tables 2 to 11.

Note that in Table 2, Comparative Example 1 was used as a standard; in Table 3, Comparative Example 4 was used a standard; in Table 4, Comparative Example 7 was used as a standard; in Table 5, Comparative Example 10 was used as a standard; in Table 6, Comparative Example 12 was used as a standard; in Table 7, Comparative Example 13 was used as a standard; in Table 8, Comparative Example 15 was used a standard; in Table 9, Comparative Example 16 was used as a standard; in Table 10, Comparative Example 17 was used as a standard, and in Table 11, Comparative Example 24 was used as a standard. Regarding organic electroluminescence elements of Examples and Comparative Examples other than those used as standard, a relative value determined when the value of external quantum efficiency of the standard Comparative Example is regarded as “100”.

TABLE 2

| | | | | Time required |
|---|---|---|---|---|
| | | | | to reach |
| | | | | one-half of |
| | Light | Electron | External | maximum |
| | emitting | transporting | Quantum | luminescence |
| | material | layer | efficiency | intensity |
| Comp. | Ir(ppy)₃ | Balq | 100 | 100 |
| Ex. 1 | | | | |
| (standard) | | | | |
| Comp. | Ir(ppy)₃ | Nitrogen- | 86 | 77 |
| Ex. 2 | | containing | | |
| | | heterocyclic | | |
| | | derivative 1 | | |
| Comp. | Ir(ppy)₃ | Nitrogen- | 84 | 81 |
| Ex. 3 | | containing | | |
| | | heterocyclic | | |
| | | derivative 2 | | |

TABLE 3

| | | | | Time required |
|---|---|---|---|---|
| | | | | to reach |
| | | | | one-half of |
| | Light | Electron | External | maximum |
| | emitting | transporting | Quantum | luminescence |
| | material | layer | efficiency | intensity |
| Comp. | FIrpic | Balq | 100 | 100 |
| Ex. 4 | | | | |
| (standard) | | | | |
| Comp. | FIrpic | Nitrogen- | 64 | 73 |
| Ex. 5 | | containing | | |
| | | heterocyclic | | |
| | | derivative 3 | | |
| Comp. | FIrpic | Nitrogen- | 75 | 74 |
| Ex. 6 | | containing | | |
| | | heterocyclic | | |
| | | derivative 4 | | |

TABLE 4

| | | | | Time required |
|---|---|---|---|---|
| | | | | to reach |
| | | | | one-half of |
| | Light | Electron | External | maximum |
| | emitting | transporting | Quantum | luminescence |
| | material | layer | efficiency | intensity |
| Comp. | Light | Balq | 100 | 100 |
| Ex. 7 | emitting | | | |
| (standard) | material A | | | |
| Comp. | Light | Nitrogen- | 91 | 92 |
| Ex. 8 | emitting | containing | | |
| | material A | heterocyclic | | |
| | | derivative 1 | | |
| Comp. | Light | Nitrogen- | 89 | 76 |
| Ex. 9 | emitting | containing | | |
| | material A | heterocyclic | | |
| | | derivative 3 | | |

TABLE 5

| | | | | Time required |
|---|---|---|---|---|
| | | | | to reach |
| | | | | one-half of |
| | Light | Electron | External | maximum |
| | emitting | transporting | Quantum | luminescence |
| | material | layer | efficiency | intensity |
| Comp. | Compound | Balq | 100 | 100 |
| Ex. 10 | (I-24) | | | |
| (standard) | | | | |
| Comp. | Compound | Alq | 95 | 81 |
| Ex. 11 | (I-24) | | | |
| Ex. 1 | Compound | Nitrogen- | 109 | 115 |
| | (I-24) | containing | | |
| | | heterocyclic | | |
| | | derivative 1 | | |
| Ex. 2 | Compound | Nitrogen- | 107 | 110 |
| | (I-24) | containing | | |
| | | heterocyclic | | |
| | | derivative 2 | | |
| Ex. 3 | Compound | Nitrogen- | 111 | 112 |
| | (I-24) | containing | | |
| | | heterocyclic | | |
| | | derivative 3 | | |

TABLE 6

| | | | | Time required |
|---|---|---|---|---|
| | | | | to reach |
| | | | | one-half of |
| | Light | Electron | External | maximum |
| | emitting | transporting | Quantum | luminescence |
| | material | layer | efficiency | intensity |
| Comp. | Compound | Balq | 100 | 100 |
| Ex. 12 | (I-26) | | | |
| (standard) | | | | |
| Ex. 4 | Compound | Nitrogen- | 119 | 118 |
| | (I-26) | containing | | |
| | | heterocyclic | | |
| | | derivative 2 | | |
| Ex. 5 | Compound | Nitrogen- | 123 | 118 |
| | (I-26) | containing | | |
| | | heterocyclic | | |
| | | derivative 3 | | |
| Ex. 6 | Compound | Nitrogen- | 122 | 117 |
| | (I-26) | containing | | |
| | | heterocyclic | | |
| | | derivative 4 | | |

TABLE 7

| | | | | Time required |
|---|---|---|---|---|
| | | | | to reach |
| | | | | one-half of |
| | Light | Electron | External | maximum |
| | emitting | transporting | Quantum | luminescence |
| | material | layer | efficiency | intensity |
| Comp. | Compound | Balq | 100 | 100 |
| Ex. 13 | (I-15) | | | |
| (standard) | | | | |
| Comp. | Compound | Alq | 98 | 70 |
| Ex. 14 | (I-15) | | | |
| Comp. | Compound | Nitrogen- | 115 | 124 |
| Ex. 18 | (I-15) | containing | | |
| | | heterocyclic | | |
| | | derivative 1 | | |
| Comp. | Compound | Nitrogen- | 112 | 128 |
| Ex. 19 | (I-15) | containing | | |
| | | heterocyclic | | |
| | | derivative 2 | | |
| Comp. | Compound | Nitrogen- | 113 | 119 |
| Ex. 20 | (I-15) | containing | | |
| | | heterocyclic | | |
| | | derivative 3 | | |

TABLE 8

| | | | | Time required |
|---|---|---|---|---|
| | | | | to reach |
| | | | | one-half of |
| | Light | Electron | External | maximum |
| | emitting | transporting | Quantum | luminescence |
| | material | layer | efficiency | intensity |
| Comp. | Compound | Balq | 100 | 100 |
| Ex. 15 | (I-16) | | | |
| (standard) | | | | |
| Ex. 10 | Compound | Nitrogen- | 117 | 111 |
| | (I-16) | containing | | |
| | | heterocyclic | | |
| | | derivative 2 | | |
| Ex. 11 | Compound | Nitrogen- | 112 | 113 |
| | (I-16) | containing | | |
| | | heterocyclic | | |
| | | derivative 3 | | |
| Ex. 12 | Compound | Nitrogen- | 114 | 115 |
| | (I-16) | containing | | |
| | | heterocyclic | | |
| | | derivative 4 | | |

TABLE 9

| | | | | Time required |
|---|---|---|---|---|
| | | | | to reach |
| | | | | one-half of |
| | Light | Electron | External | maximum |
| | emitting | transporting | Quantum | luminescence |
| | material | layer | efficiency | intensity |
| Comp. | Compound | Balq | 100 | 100 |
| Ex. 16 | (I-20) | | | |
| (standard) | | | | |
| Ex. 13 | Compound | Nitrogen- | 123 | 107 |
| | (I-20) | containing | | |
| | | heterocyclic | | |
| | | derivative 1 | | |
| Ex. 14 | Compound | Nitrogen- | 121 | 106 |
| | (I-20) | containing | | |
| | | heterocyclic | | |
| | | derivative 2 | | |
| Ex. 15 | Compound | Nitrogen- | 118 | 107 |
| | (I-20) | containing | | |
| | | heterocyclic | | |
| | | derivative 3 | | |

TABLE 10

| | | | | Time required |
|---|---|---|---|---|
| | | | | to reach |
| | | | | one-half of |
| | Light | Electron | External | maximum |
| | emitting | transporting | Quantum | luminescence |
| | material | layer | efficiency | intensity |
| Comp. | Compound | Balq | 100 | 100 |
| Ex. 17 | (I-5) | | | |
| (standard) | | | | |
| Comp. | Compound | Nitrogen- | 108 | 116 |
| Ex. 21 | (I-5) | containing | | |
| | | heterocyclic | | |
| | | derivative 2 | | |
| Comp. | Compound | Nitrogen- | 109 | 107 |
| Ex. 22 | (I-5) | containing | | |
| | | heterocyclic | | |
| | | derivative 3 | | |
| Comp. | Compound | Nitrogen- | 108 | 109 |
| Ex. 23 | (I-5) | containing | | |
| | | heterocyclic | | |
| | | derivative 4 | | |

TABLE 11

| | | | | Time required |
|---|---|---|---|---|
| | | | | to reach |
| | | | | one-half of |
| | Light | Electron | External | maximum |
| | emitting | transporting | Quantum | luminescence |
| | material | layer | efficiency | intensity |
| Comp. | Compound | Balq | 100 | 100 |
| Ex. 24 | (I-4) | | | |
| (standard) | | | | |
| Ex. 16 | Compound | Nitrogen- | 126 | 125 |
| | (I-4) | containing | | |
| | | heterocyclic | | |
| | | derivative 1 | | |
| Ex. 17 | Compound | Nitrogen- | 118 | 115 |
| | (I-4) | containing | | |
| | | heterocyclic | | |
| | | derivative 3 | | |

The results shown in Tables 2 to 11 demonstrated that in the case of using a phosphorescence emitting material represented by any one of General Formulae (2A), (2B), and (2C) as a light emitting material, the organic electroluminescence elements each having an electron transporting layer doped with a nitrogen-containing heterocyclic derivative represented by General Formula (1) were superior in the external quantum efficiency and the time required to reach one-half of the maximum luminescence intensity to those having an electron transporting layer doped with Balq.

On the other hand, it was found that in the case of using a material other than the phosphorescence emitting materials each represented by any one of General Formulae (2A), (2B), and (2C) as a light emitting material, the organic electroluminescence elements each having an electron transporting layer doped with a nitrogen-containing heterocyclic derivative represented by General Formula (1) were inferior in the external quantum efficiency and the time required to reach one-half of the maximum luminescence intensity to those having an electron transporting layer doped with Balq.

Since the organic electroluminescence elements of the present invention can satisfy both excellent light emitting efficiency and long light emission life, they are suitably used, for example, for display elements, displays, backlights, electrophotography, light sources for illumination, light sources for recording, light sources for exposure, light sources for reading, signs, sign boards, interiors, and optical communications.

1. An organic electroluminescence element comprising:
an anode,
a cathode, and
at least one organic layer which comprises a light emitting layer, and which is provided between the anode and the cathode,
wherein at least one layer in the organic layer contains at least one selected from nitrogen-containing heterocyclic derivatives each represented by the following General Formula (1) and used as at least one of an electron injecting material and an electron transporting material, and at least one layer in the organic layer contains at least one selected from phosphorescence emitting materials having structures expressed by the following Structural Formulae (I-1) to (I-4), (I-7) to (I-12), (I-14) and (I-16) to (I-26): 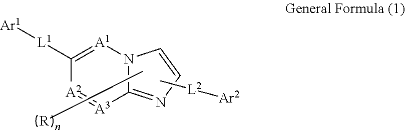
where A¹ to A³ independently represent a nitrogen atom or a carbon atom; Ar¹ represents a substituted or unsubstituted aryl group having 6 to 60 nuclear carbon atoms or a substituted or unsubstituted heteroaryl group having 3 to 60 nuclear carbon atoms; Ar² represents any one of a hydrogen atom, a substituted or unsubstituted aryl group having 6 to 60 nuclear carbon atoms, a substituted or unsubstituted heteroaryl group having 3 to 60 nuclear carbon atoms, a substituted or unsubstituted alkyl group having 1 to 20 carbon atoms and a substituted or unsubstituted alkoxy group having 1 to 20 carbon atoms, provided that one of Ar¹ and Ar² is a substituted or unsubstituted condensed ring group having 10 to 60 nuclear carbon atoms or a substituted or unsubstituted monohetero-condensed ring group having 3 to 60 nuclear carbon atoms; L¹ and L² independently represent any one of a single bond, a substituted or unsubstituted arylene group having 6 to 60 nuclear carbon atoms, a substituted or unsubstituted heteroarylene group having 3 to 60 nuclear carbon atoms and a substituted or unsubstituted fluorenylene group; R represents any one of a hydrogen atom, a substituted or unsubstituted aryl group having 6 to 60 nuclear carbon atoms, a substituted or unsubstituted heteroaryl group having 3 to 60 nuclear carbon atoms, a substituted or unsubstituted alkyl group having 1 to 20 carbon atoms and a substituted or unsubstituted alkoxy group having 1 to 20 carbon atoms; n is an integer of 0 to 5, and when n is 2 or more, Rs may be identical to or different from each other, and adjacent R groups may be bonded to each other to form a carbon cyclic aliphatic ring or a carbon cyclic aromatic ring,

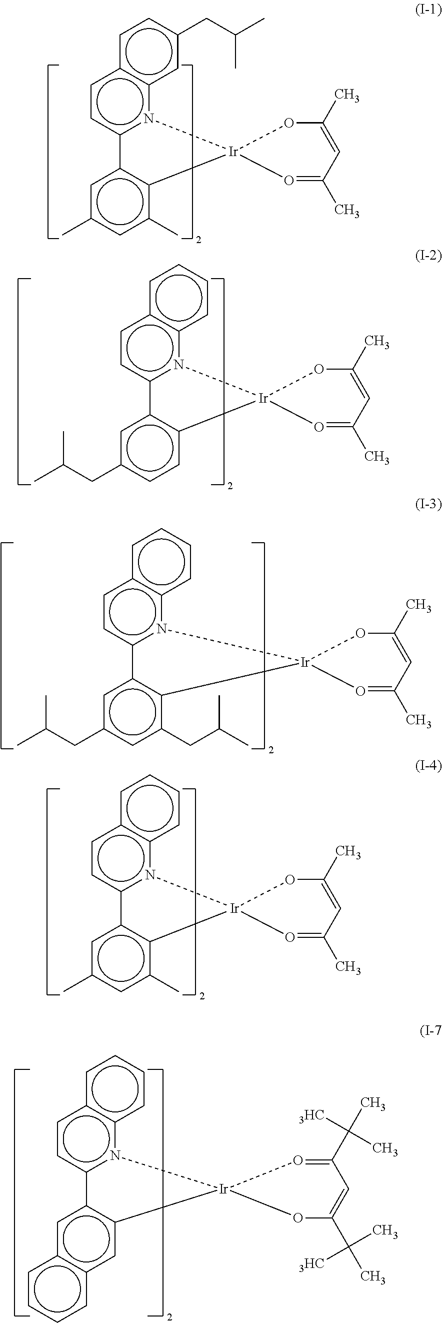

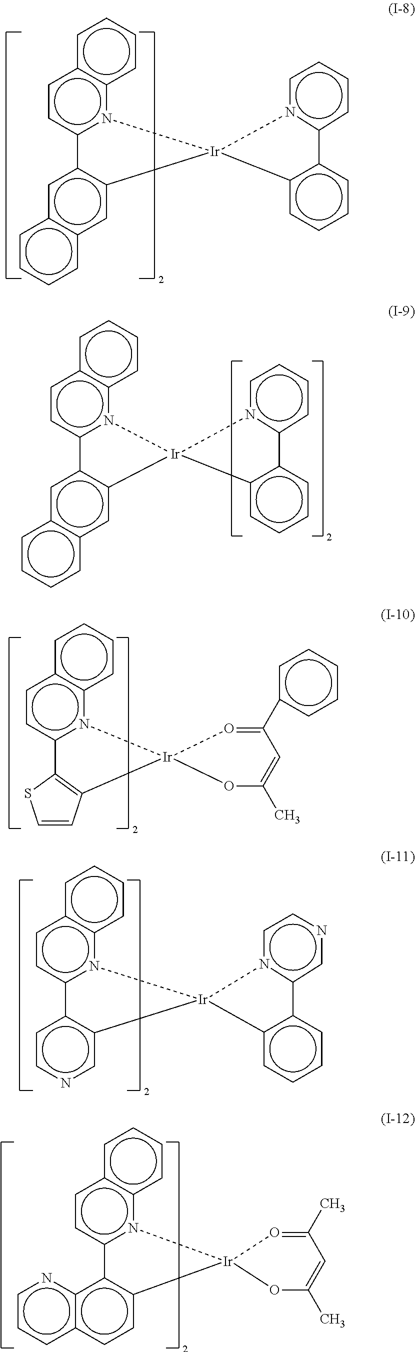

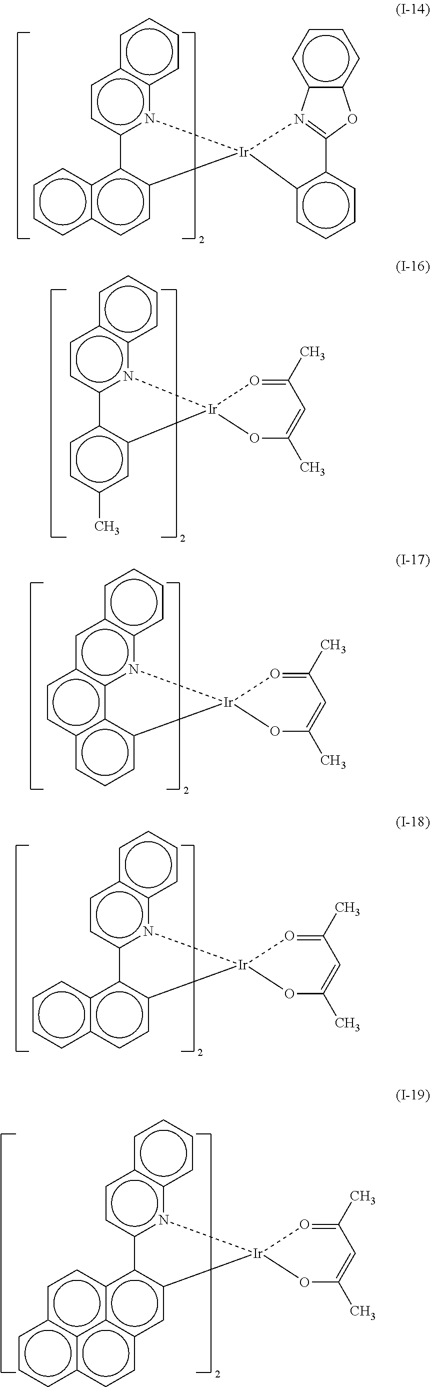

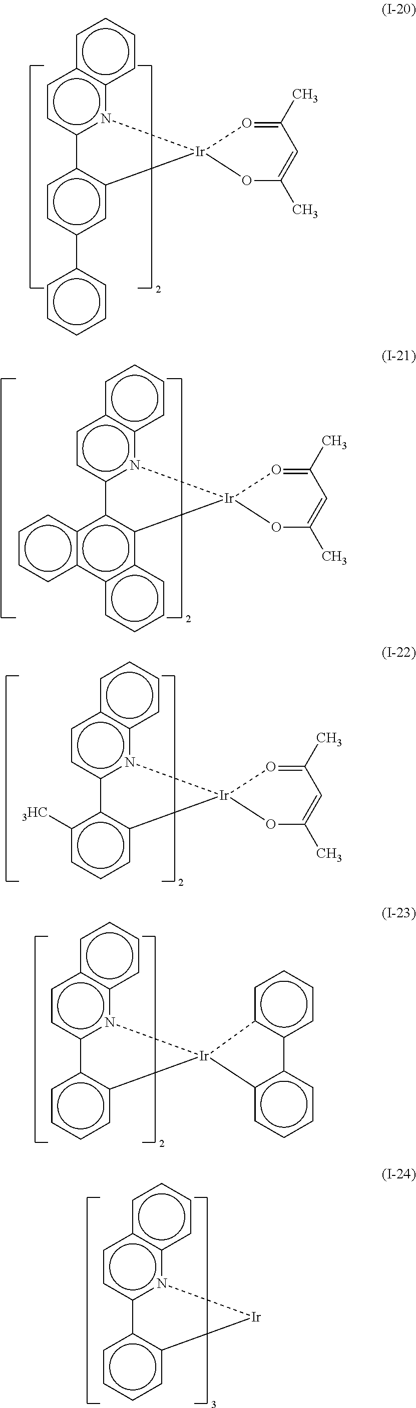

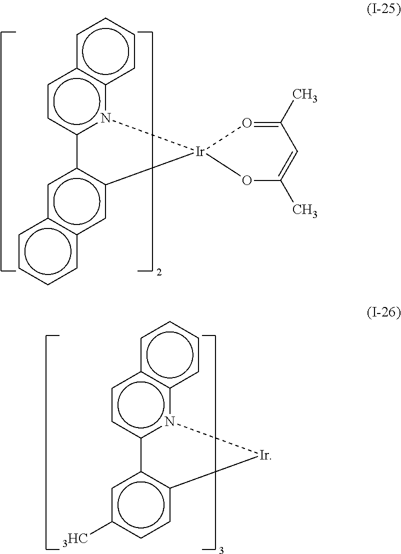

2. The organic electroluminescence element according to claim 1, wherein the nitrogen-containing heterocyclic derivative represented by General Formula (1) is a nitrogen-containing heterocyclic derivative represented by the following General Formula (4): 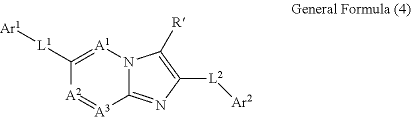
where A¹ to A³ independently represent a nitrogen atom or a carbon atom; Ar¹ represents a substituted or unsubstituted aryl group having 6 to 60 nuclear carbon atoms or a substituted or unsubstituted heteroaryl group having 3 to 60 nuclear carbon atoms; Ar² represents any one of a hydrogen atom, a substituted or unsubstituted aryl group having 6 to 60 nuclear carbon atoms, a substituted or unsubstituted heteroaryl group having 3 to 60 nuclear carbon atoms, a substituted or unsubstituted alkyl group having 1 to 20 carbon atoms and a substituted or unsubstituted alkoxy group having 1 to 20 carbon atoms, provided that one of Ar¹ and Ar² is a substituted or unsubstituted condensed ring group having 10 to 60 nuclear carbon atoms or a substituted or unsubstituted monohetero-condensed ring group having 3 to 60 nuclear carbon atoms; L¹ and L² independently represent any one of a single bond, a substituted or unsubstituted arylene group having 6 to 60 nuclear carbon atoms, a substituted or unsubstituted heteroarylene group having 3 to 60 nuclear carbon atoms and a substituted or unsubstituted fluorenylene group; and R′ represents any one of a hydrogen atom, a substituted or unsubstituted aryl group having 6 to 60 nuclear carbon atoms, a substituted or unsubstituted heteroaryl group having 3 to 60 nuclear carbon atoms, a substituted or unsubstituted alkyl group having 1 to 20 carbon atoms and a substituted or unsubstituted alkoxy group having 1 to 20 carbon atoms.

3. The organic electroluminescence element according to claim 2, wherein the nitrogen-containing heterocyclic derivative represented by General Formula (4) is a nitrogen-containing heterocyclic derivative represented by the following General Formula (5): 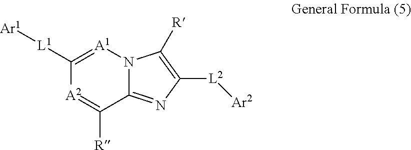
where A¹ and A² independently represent a nitrogen atom or a carbon atom; Ar¹ represents a substituted or unsubstituted aryl group having 6 to 60 nuclear carbon atoms or a substituted or unsubstituted heteroaryl group having 3 to 60 nuclear carbon atoms; Ar² represents any one of a hydrogen atom, a substituted or unsubstituted aryl group having 6 to 60 nuclear carbon atoms, a substituted or unsubstituted heteroaryl group having 3 to 60 nuclear carbon atoms, a substituted or unsubstituted alkyl group having 1 to 20 carbon atoms and a substituted or unsubstituted alkoxy group having 1 to 20 carbon atoms, provided that one of Ar¹ and Ar² is a substituted or unsubstituted condensed ring group having 10 to 60 nuclear carbon atoms or a substituted or unsubstituted monohetero-condensed ring group having 3 to 60 nuclear carbon atoms; L¹ and L² independently represent any one of a single bond, a substituted or unsubstituted arylene group having 6 to 60 nuclear carbon atoms, a substituted or unsubstituted heteroarylene group having 3 to 60 nuclear carbon atoms and a substituted or unsubstituted fluorenylene group; R′ and R″ independently represent any one of a hydrogen atom, a substituted or unsubstituted aryl group having 6 to 60 nuclear carbon atoms, a substituted or unsubstituted heteroaryl group having 3 to 60 nuclear carbon atoms, a substituted or unsubstituted alkyl group having 1 to 20 carbon atoms and a substituted or unsubstituted alkoxy group having 1 to 20 carbon atoms, and R′ and R″ may be identical to or different from each other.

4. The organic electroluminescence element according to claim 1, wherein in the nitrogen-containing heterocyclic derivative represented by at least one of General Formulae (1), (4), and (5), at least one of L¹ and L² is selected from groups represented by the following structural formulae:

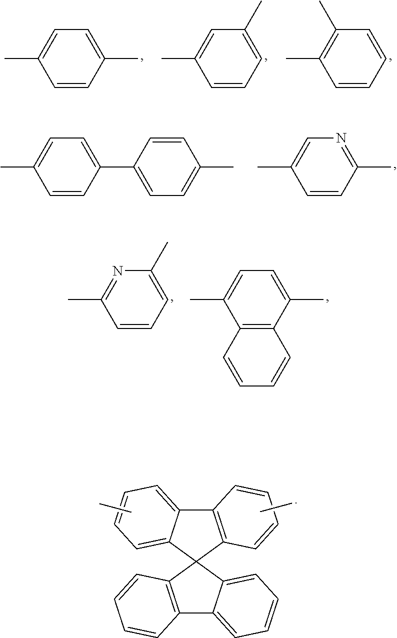

5. The organic electroluminescence element according to claim 1, wherein in the nitrogen-containing heterocyclic derivative represented by at least one of General Formulae (1), (4), and (5), Ar¹ is selected from groups represented by the following General Formulae (6) to (15): 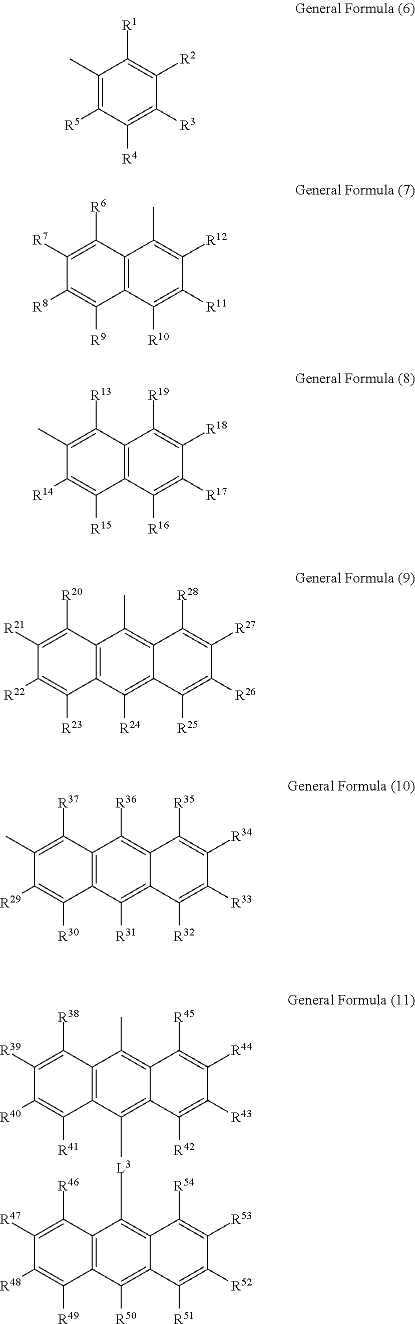 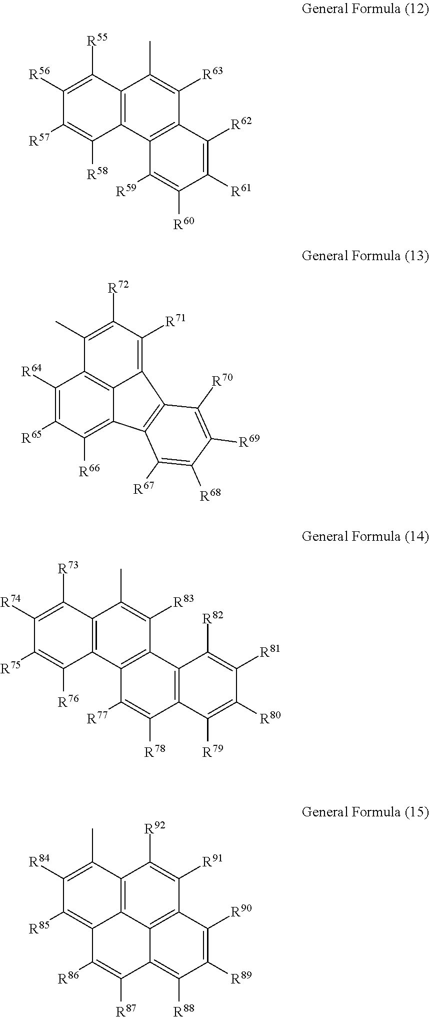
in General Formulae (6) to (15), R¹ to R⁹² independently represent any one of a hydrogen atom, a halogen atom, a substituted or unsubstituted alkyl group having 1 to 20 carbon atoms, a substituted or unsubstituted alkoxy group having 1 to 20 carbon atoms, a substituted or unsubstituted aryloxy group having 6 to 40 nuclear carbon atoms, a substituted or unsubstituted diarylamino group having 12 to 80 nuclear carbon atoms, a substituted or unsubstituted aryl group having 6 to 40 nuclear carbon atoms, a substituted or unsubstituted heteroaryl group having 3 to 40 nuclear carbon atoms and a substituted or unsubstituted diarylaminoaryl group having 18 to 120 nuclear carbon atoms; and L³ represents one of a single bond and a substituent represented by any one of the following structural formulae: [chemical structure]
